(19) United States
(12) Patent Application Publication
(10) Pub. No.: US 2015/0206973 A1
(43) Pub. Date: Jul. 23, 2015

(54) SEMICONDUCTOR DEVICE AND METHOD FOR MANUFACTURING SAME

(71) Applicant: PS4 Luxco S.a.r.l., Luxembourg (LU)

(72) Inventor: Kiyonori Oyu, Tokyo (JP)

(73) Assignee: PS4 Luxco S.a.r.l, Luxembourg (LU)

(21) Appl. No.: 14/421,974

(22) PCT Filed: Aug. 16, 2013
(86) PCT No.: PCT/JP2013/072014

§ 371 Date: Feb. 16, 2015

(30) Foreign Application Priority Data
Aug. 17, 2012 (JP) 2012-181130

(51) Int. Cl. H01L 29/78; H01L 29/423; H01L 27/088; H01L 21/321; H01L 21/306; H01L 21/308; H01L 21/3213; H01L 29/66; H01L 21/8234

(52) U.S. Cl. CPC H01L 29/7851; H01L 29/66795; H01L 29/4232; H01L 27/0886; H01L 21/823431; H01L 21/823437; H01L 21/30604; H01L 21/308; H01L 21/32135; H01L 21/32115

(57) ABSTRACT

[Problem] To suppress damage to a semiconductor beam or a semiconductor substrate resulting from dry etching of gate electrode material during manufacture.

[Solution] A method according to the present invention comprises: a step of forming dopant-diffused layers 5A, 5B on the main surface of a semiconductor substrate 1; a step of forming a trench 11 on a bottom surface of which is erected at least one semiconductor beam 4, each connected at one end to the dopant-diffused layer 5A and connected at the other end to the dopant-diffused layer 5B; a step of forming a gate insulating film 6 on an inner surface of the trench 11, including the side surfaces of each at least one semiconductor beam 4, and on an upper surface of each at least one semiconductor beam 4; a step of depositing a gate electrode material having a film thickness that fills the trench 11, after the gate insulating film 6 has been formed; and a step of removing the gate electrode material that is located outside the trench 11 as seen in a plan view, while leaving the gate electrode material that is located inside the trench 11 as seen in a plan view.

### TECHNICAL FIELD

The present invention relates to a semiconductor device and a method for manufacturing the same, and in particular relates to a semiconductor device employing a fin-type FET and a method for manufacturing the same.

### BACKGROUND ART

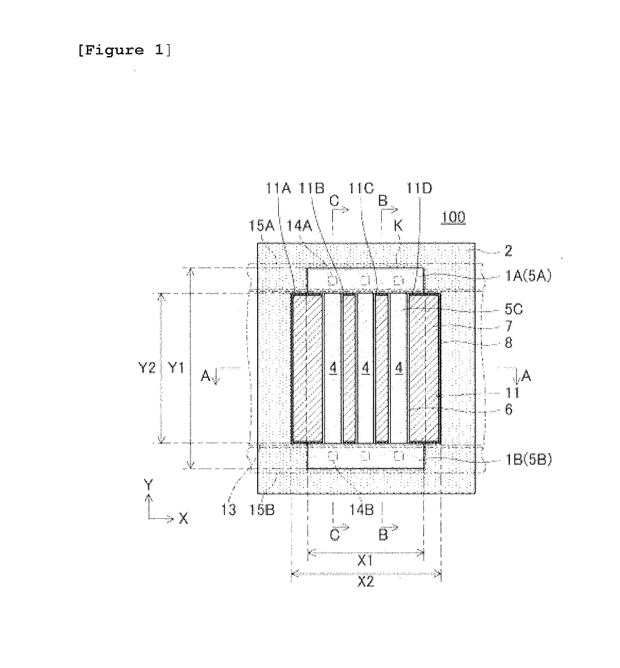

A fin-type FET, which is one type of field-effect transistor, has a construction in which a thin fin-shaped silicon layer (hereinafter referred to as a ‘semiconductor beam’) erected on the surface of a semiconductor substrate is covered from three directions (the upper surface and the two side surfaces) by a gate electrode. FIG. 1 in patent literature article 1, for example, discloses an example of such a fin-type FET.

As illustrated in FIG. 1 of patent literature article 1, the planar shape of the semiconductor beam is rectangular, a source region and a drain region being connected respectively to one end and the other end thereof in the longitudinal direction. The gate electrode is formed in such a way that middle of the semiconductor beam in the longitudinal direction is covered from the abovementioned three directions, the planar shape thereof being a rectangle having a longitudinal direction oriented in a direction orthogonal to the longitudinal direction of the semiconductor beam.

### PRIOR ART LITERATURE

### Patent literature

Patent literature article 1: Japanese Translation of PCT International Application 2006-511091

### SUMMARY OF THE INVENTION

### Problems to be Resolved by the Invention

However, the abovementioned fin-type FET has a problem in that there is a risk that the semiconductor beam or the semiconductor substrate may be damaged during the course of manufacture. This is because the semiconductor beam and the semiconductor substrate are exposed to excessive dry etching when the gate electrode is formed. This will now be described in detail.

In the process of forming the gate electrode, first a gate insulating film and a gate electrode material are formed in succession over the entire surface of the semiconductor beam, including the upper surface and the side surfaces. The film thickness in the perpendicular direction of the gate electrode material formed in this way differs greatly between sections formed on the side surfaces of the semiconductor beam and other sections. To elaborate, in the latter case the film thickness (X hereinafter) is determined in accordance with the amount of deposition, whereas in the former case the film thickness is increased by the height of the semiconductor beam (X+H hereinafter. H is the height of the semiconductor beam). After the gate electrode material has been formed, a masking film is used to cover the sections of the gate electrode material that are to remain as the gate electrode. Other sections of the gate electrode material are removed by anisotropic dry etching, with the masking film serving as a mask.

In the abovementioned dry etching, the gate electrode material formed on the side surfaces of the semiconductor beam is also subject to removal. Therefore, the duration of the dry etching must be set to a time that allows the gate electrode material having a film thickness of X+H to be removed adequately. However, if dry etching is performed with such a setting, dry etching continues to occur in the sections other than the side surfaces of the semiconductor beam even after the gate electrode material having a film thickness of X has been removed. As a result the gate insulating film, and the semiconductor beam and the semiconductor substrate thereunder are directly exposed to dry etching, and thus damage to the semiconductor beam and the semiconductor substrate is a concern.

### Means of Overcoming the Problems

The method of manufacturing a semiconductor device according to the present invention is characterized in that it comprises: a step of forming a first and a second dopant-diffused layer on the main surface of a semiconductor substrate; a step of forming a trench on a bottom surface of which is erected at least one semiconductor beam, each connected at one end to the abovementioned first dopant-diffused layer and connected at the other end to the abovementioned second dopant-diffused layer; a step of forming a gate insulating film on an inner surface of the abovementioned trench, including the side surfaces of each abovementioned at least one semiconductor beam, and on an upper surface of each abovementioned at least one semiconductor beam; a step of depositing a gate electrode material having a film thickness that exceeds the respective upper surfaces of each abovementioned at least one semiconductor beam, after the abovementioned gate insulating film has been formed; and a step of removing the abovementioned gate electrode material that is located outside the abovementioned trench as seen in a plan view, while leaving the abovementioned gate electrode material that is located inside the abovementioned trench as seen in a plan view.

The semiconductor device according to the present invention is characterized in that it comprises: a first and a second dopant-diffused layer formed on the main surface of a semiconductor substrate; a trench on a bottom surface of which is erected at least one semiconductor beam, each connected at one end to the abovementioned first dopant-diffused layer and connected at the other end to the abovementioned second dopant-diffused layer; a gate insulating film covering an inner surface of the abovementioned trench, including the side surfaces of each abovementioned at least one semiconductor beam, and an upper surface of each abovementioned at least one semiconductor beam; and a gate electrode covering, with the interposition of the abovementioned gate insulating film, the inner surface of the abovementioned trench, including the side surfaces of each abovementioned at least one semiconductor beam, and the upper surface of each abovementioned at least one semiconductor beam.

### Advantages of the Invention

According to the present invention, it is possible to form the gate electrode by dry etching (in the first mode of embodiment discussed hereinafter) only sections of the gate electrode material that have been formed to a given film thickness, or by grinding the gate electrode material using a CMP method or the like (in the second mode of embodiment discussed hereinafter). Damage to the semiconductor beam or the semiconductor substrate resulting from the dry etching of the gate electrode material is therefore significantly suppressed compared with the background art discussed hereinabove.

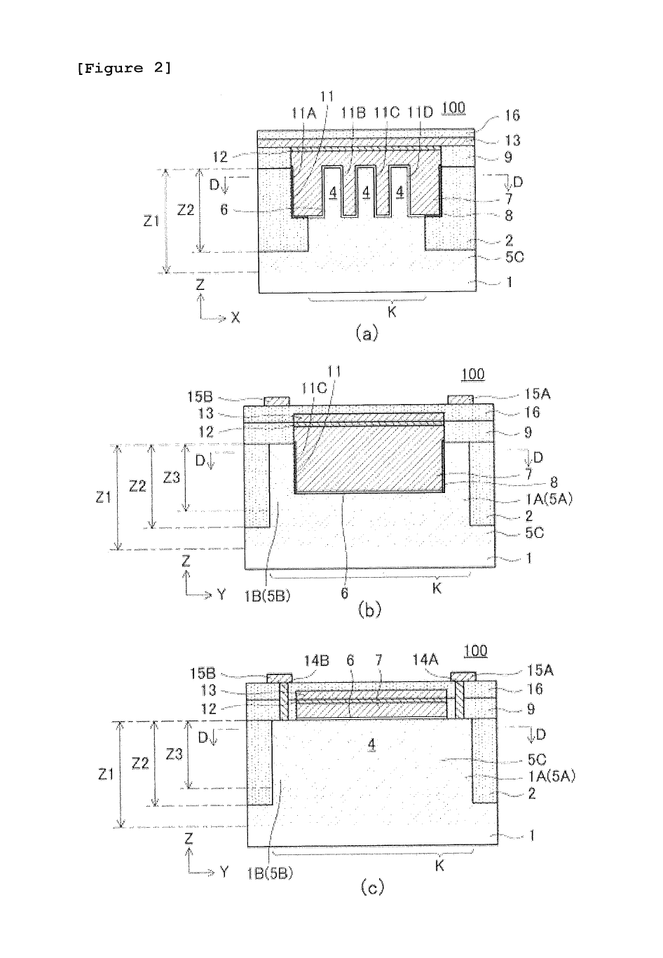

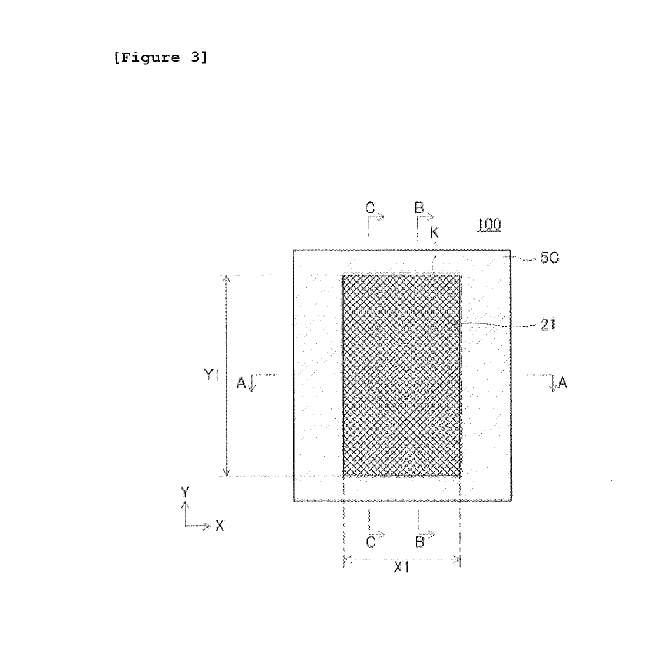

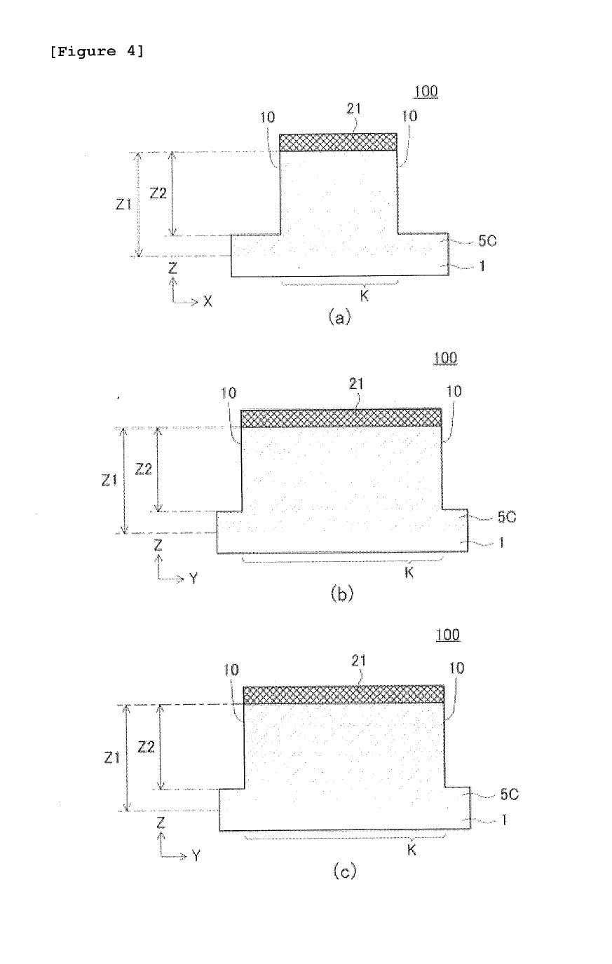

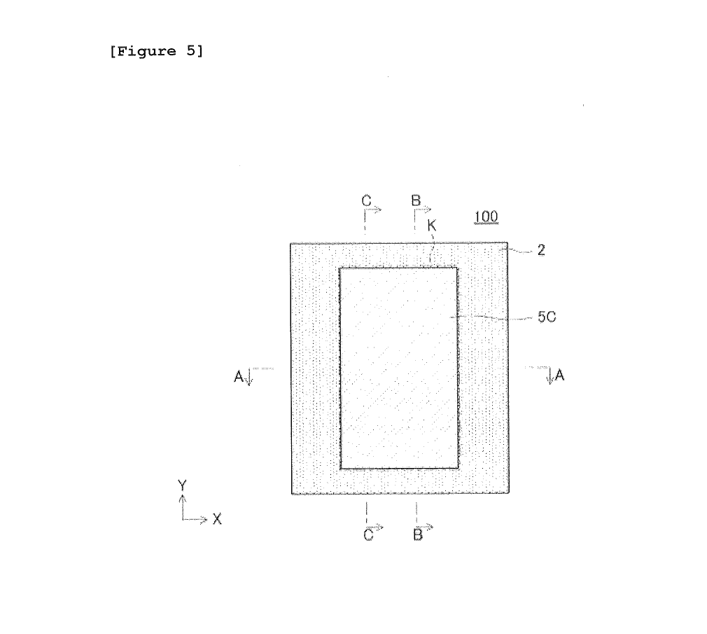

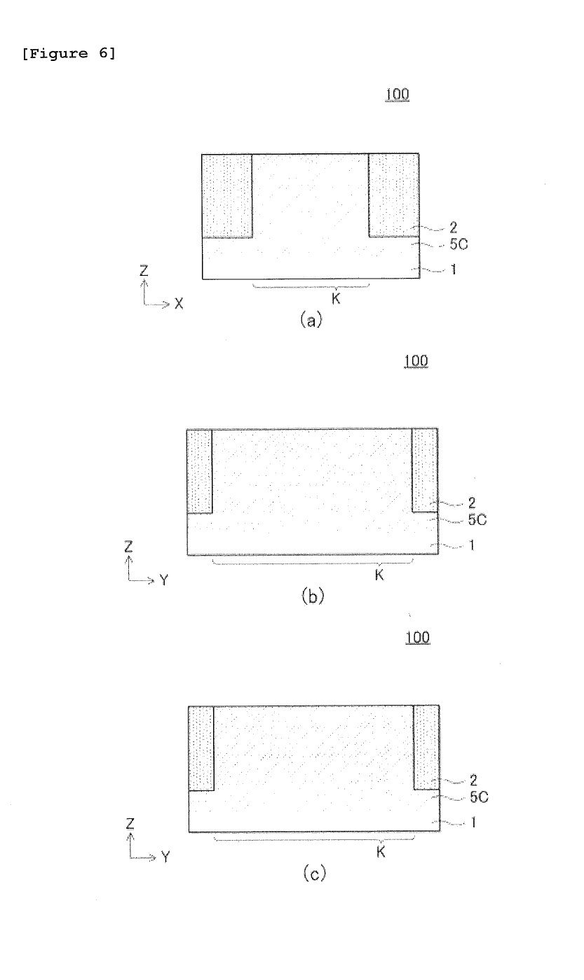

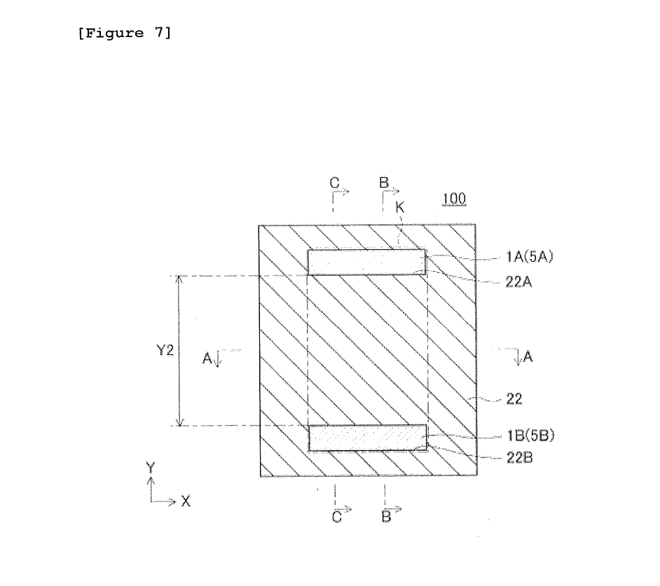

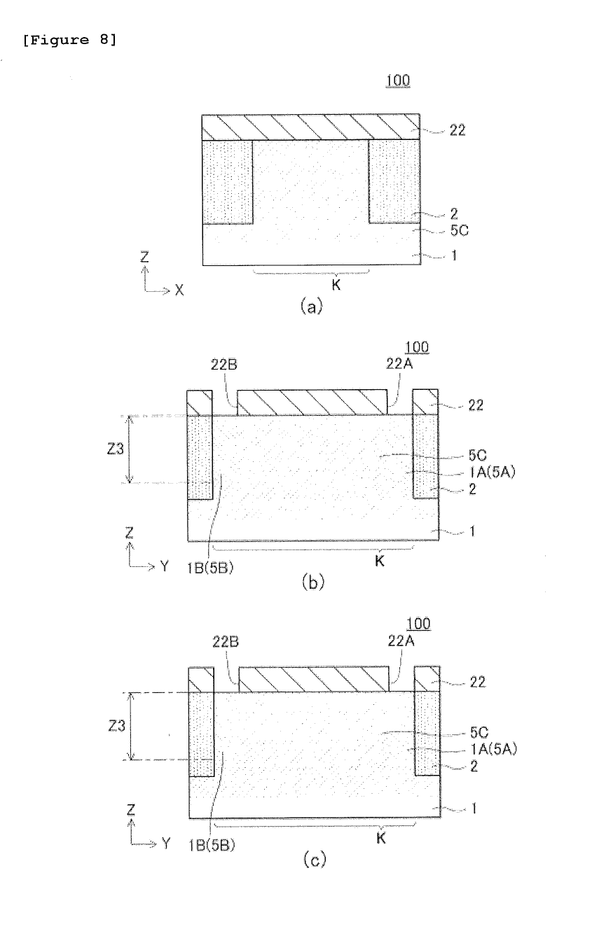

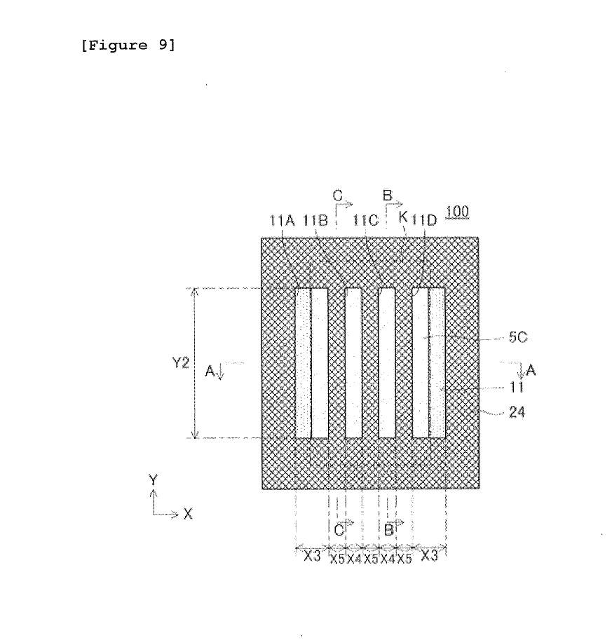

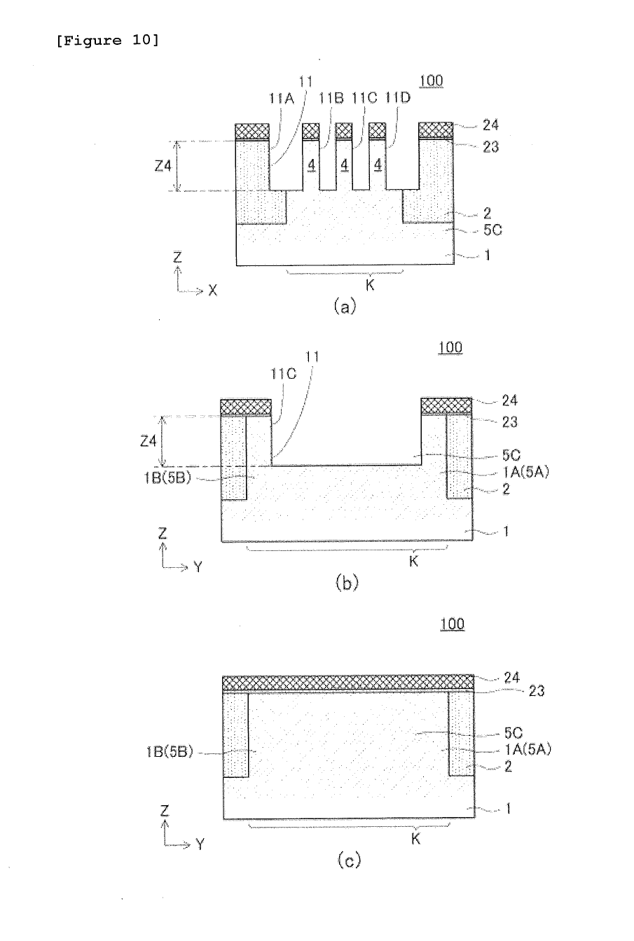

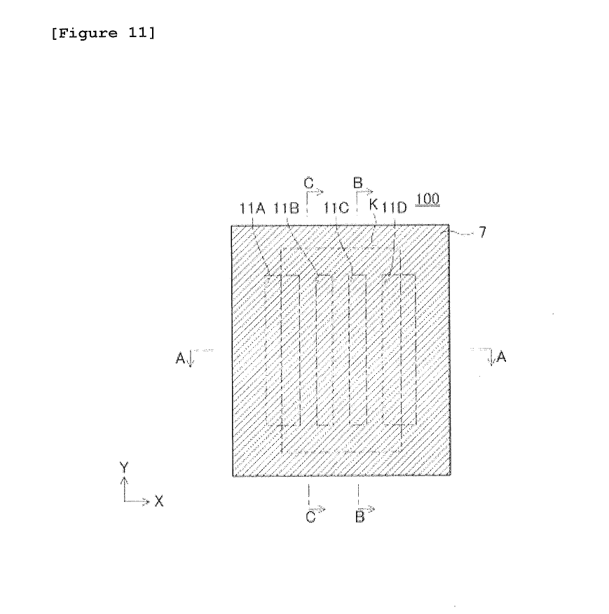

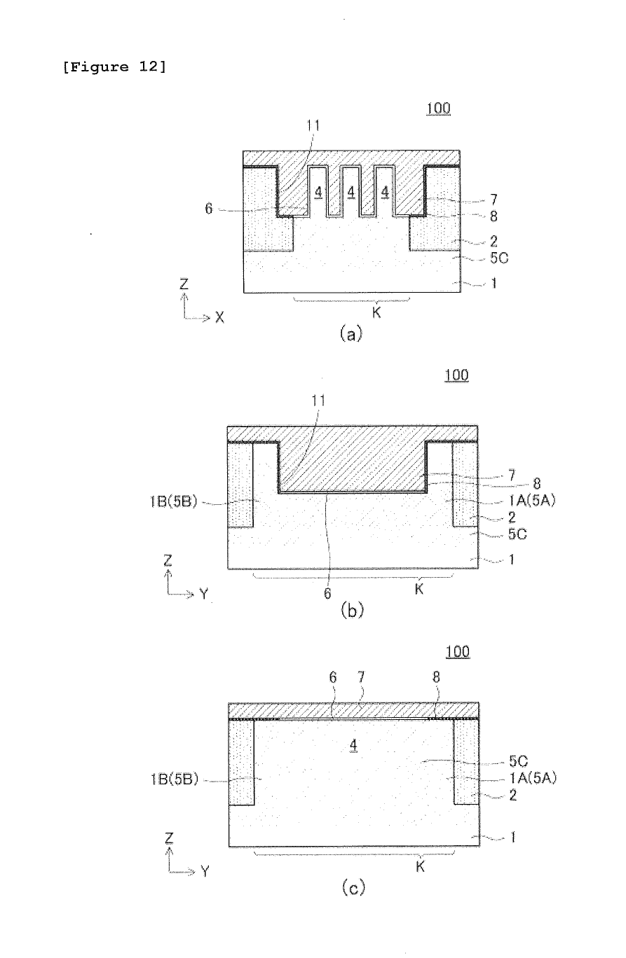

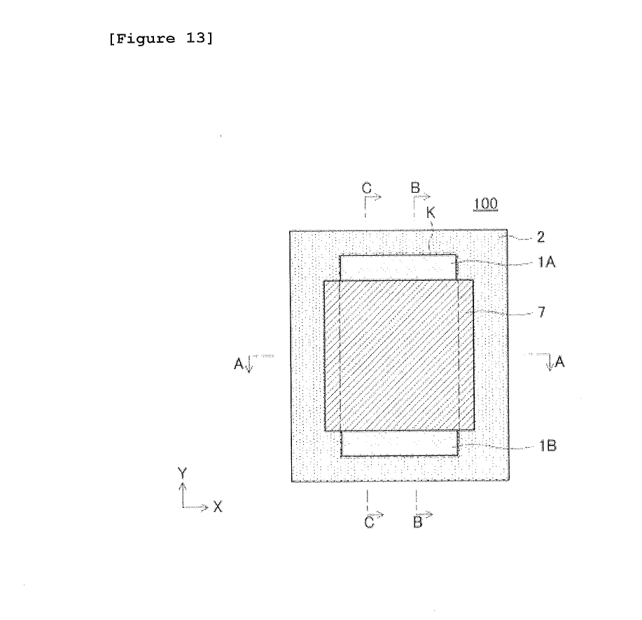

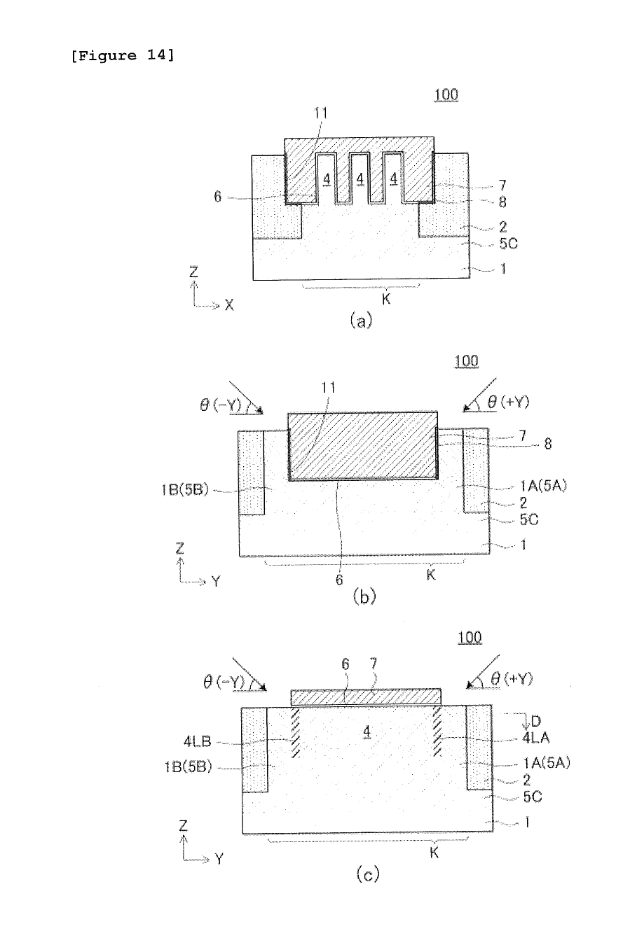

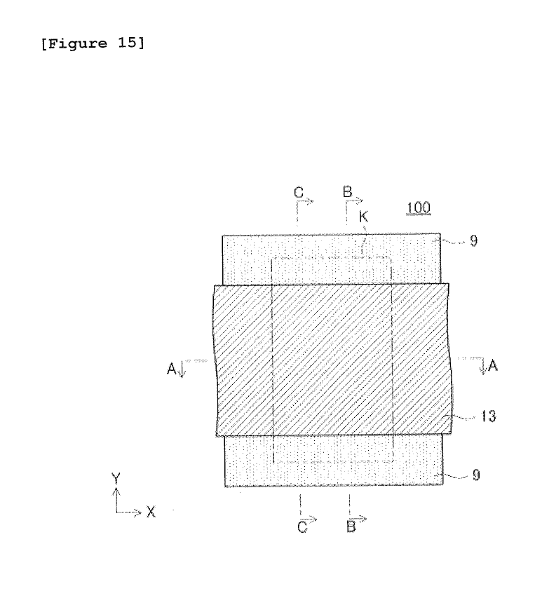

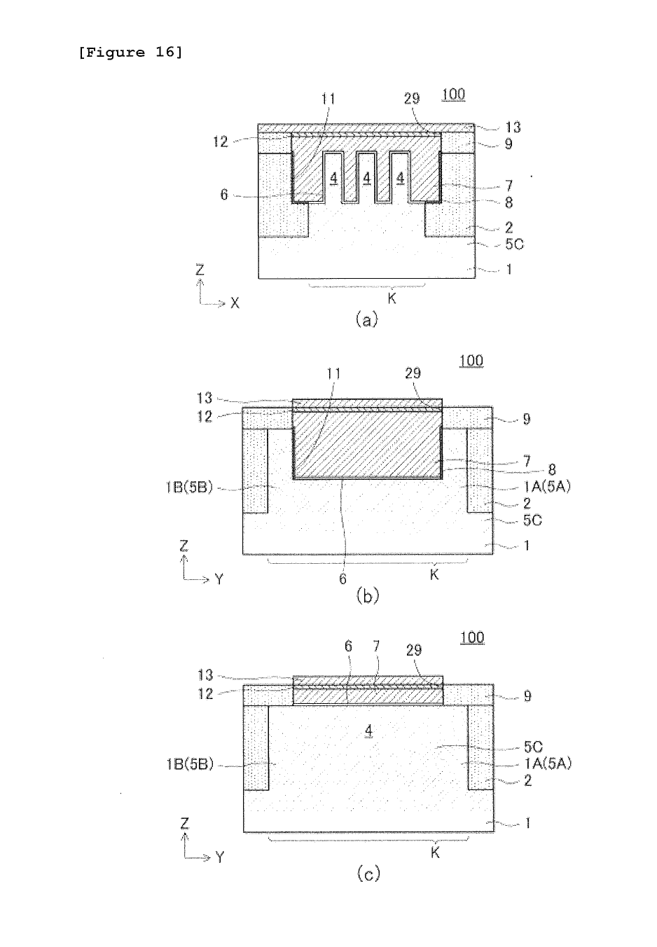

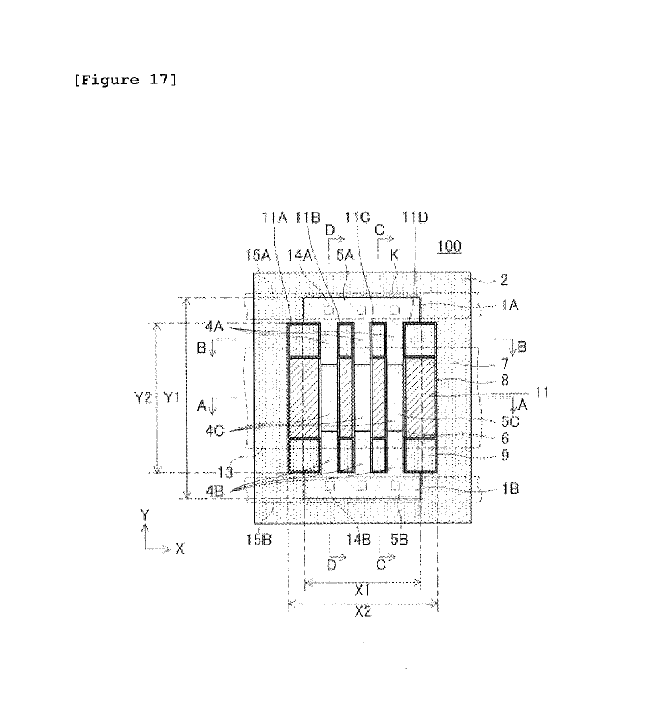

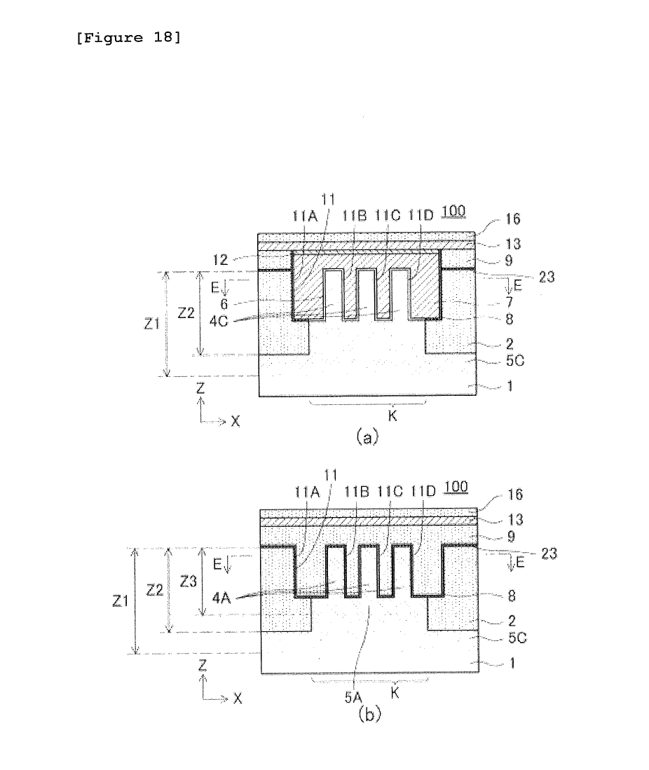

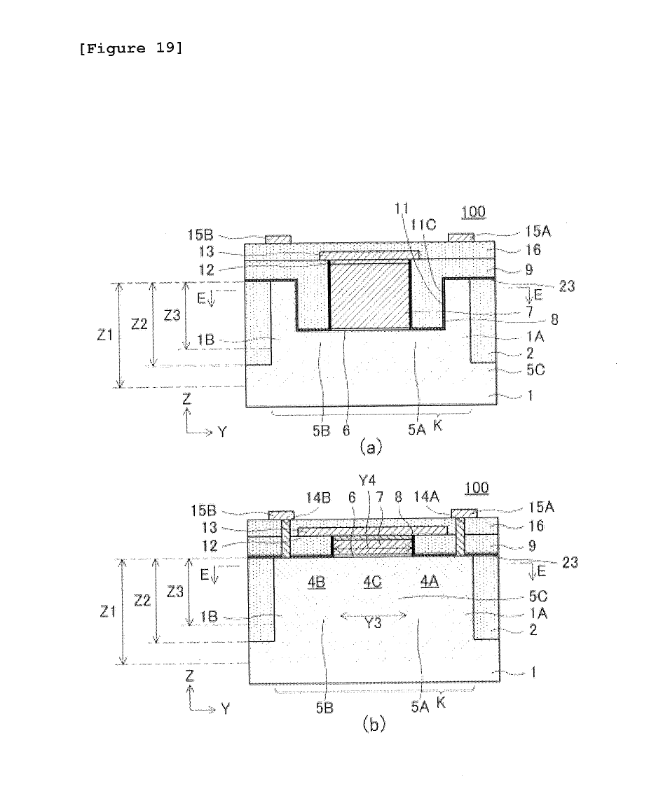

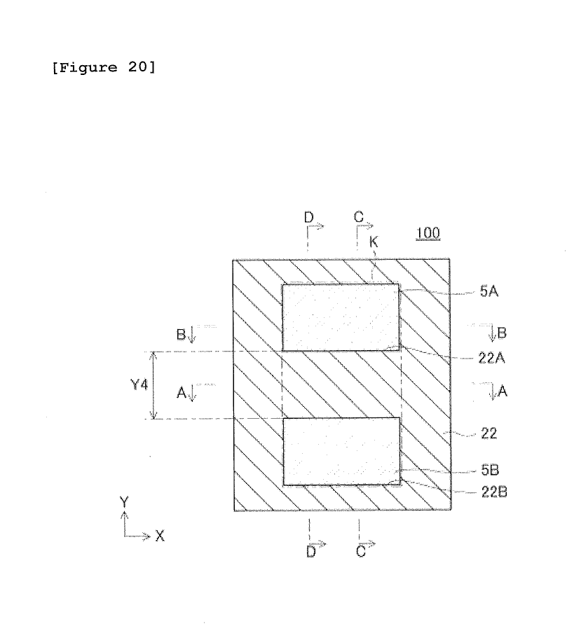

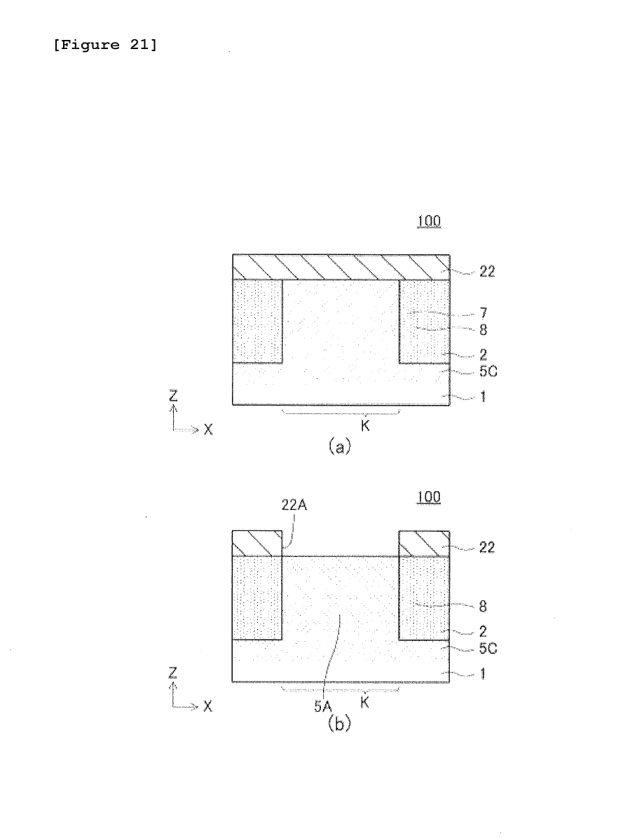

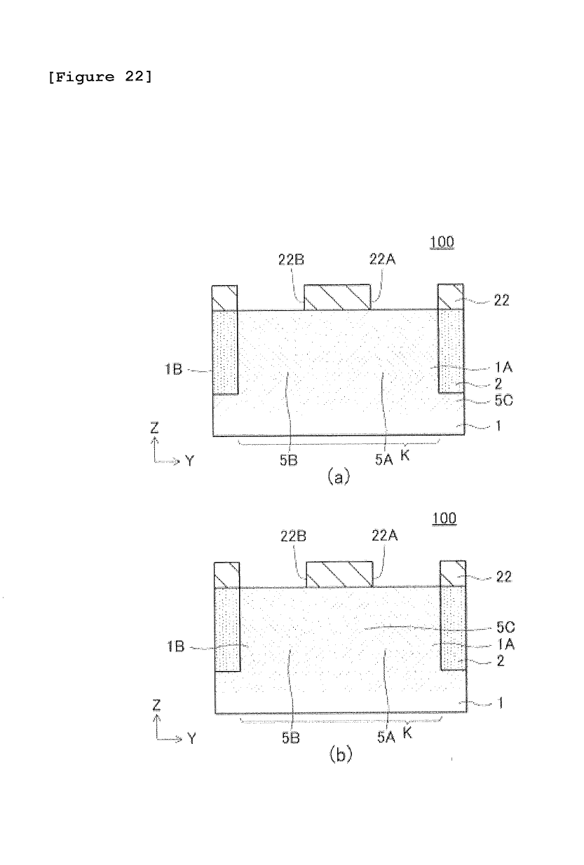

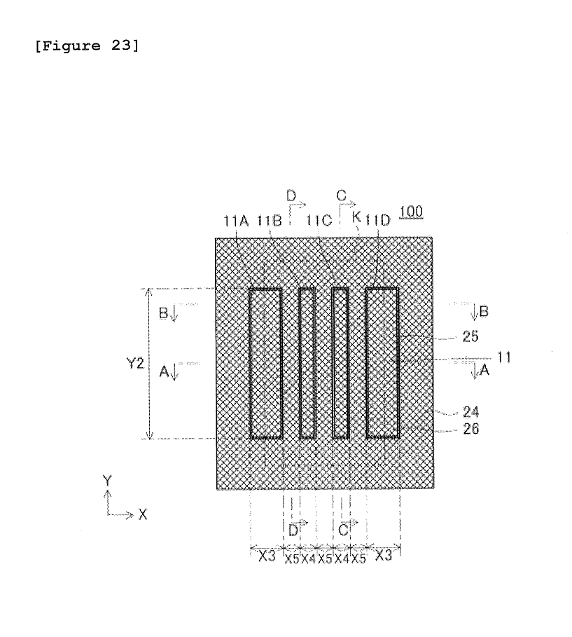

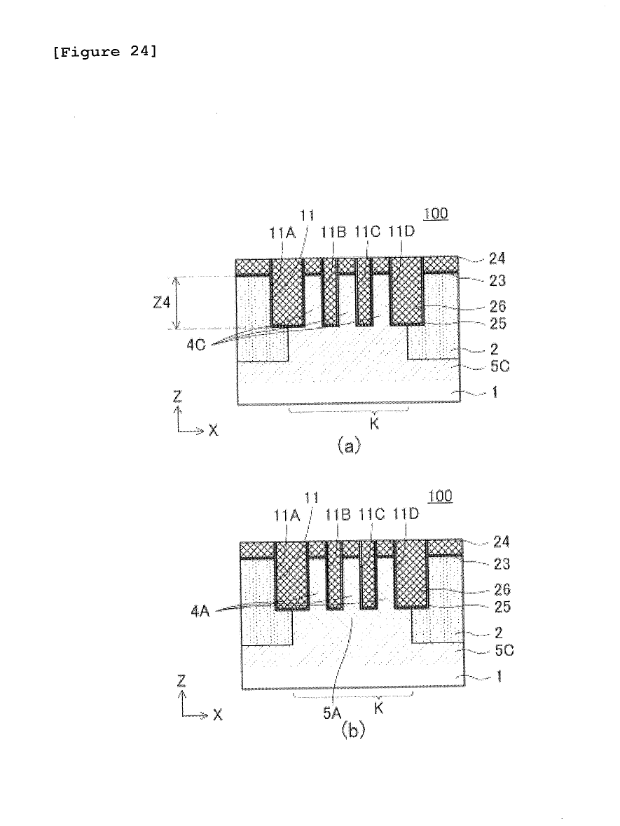

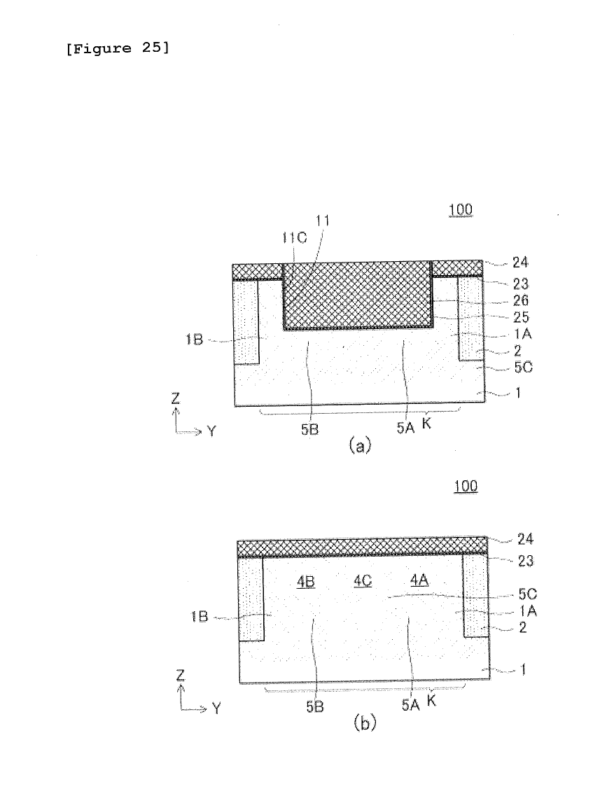

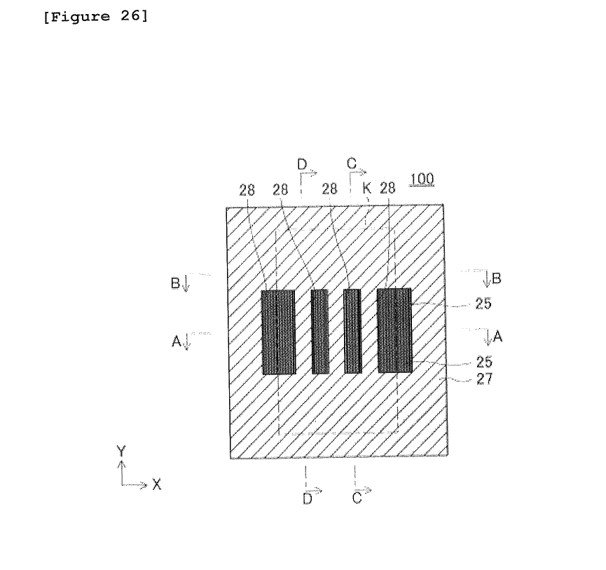

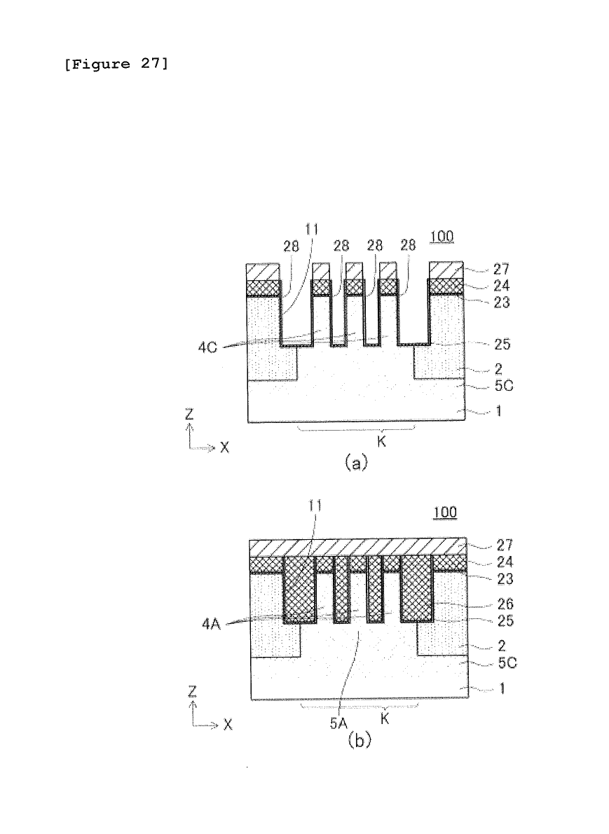

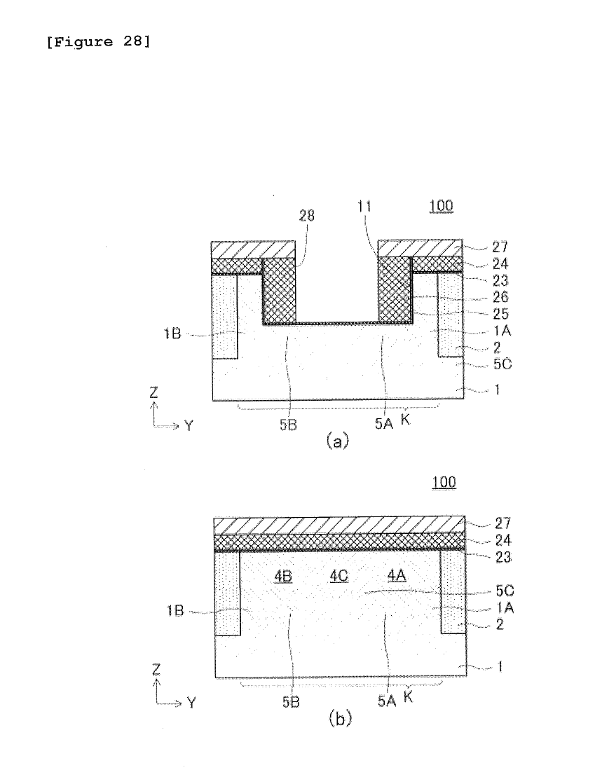

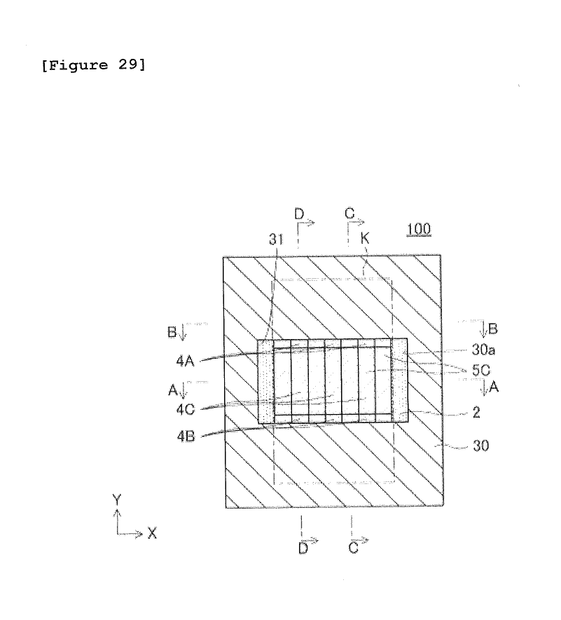

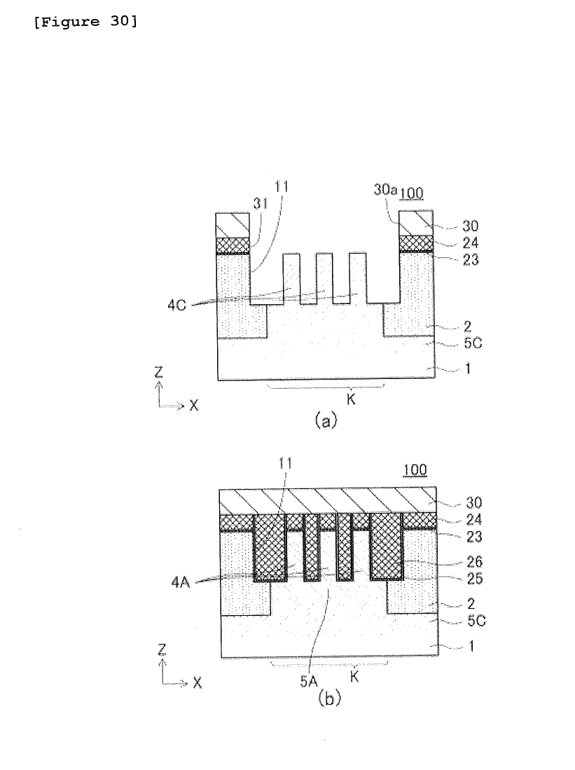

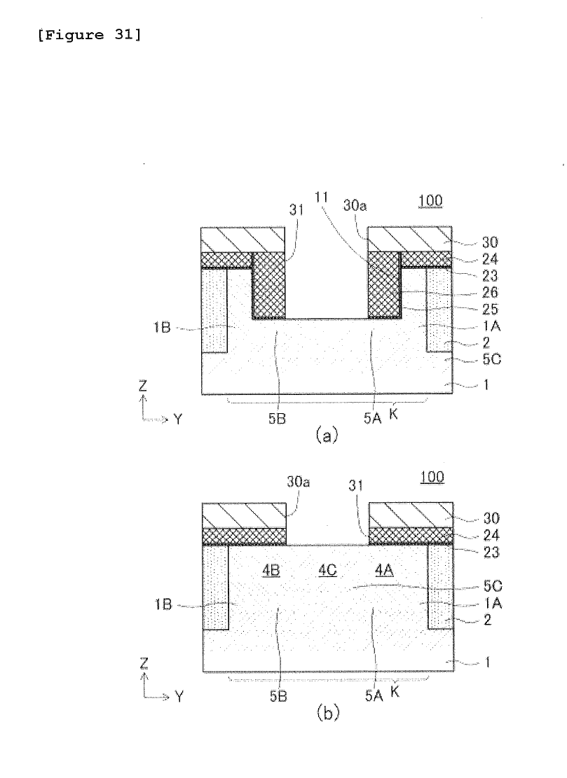

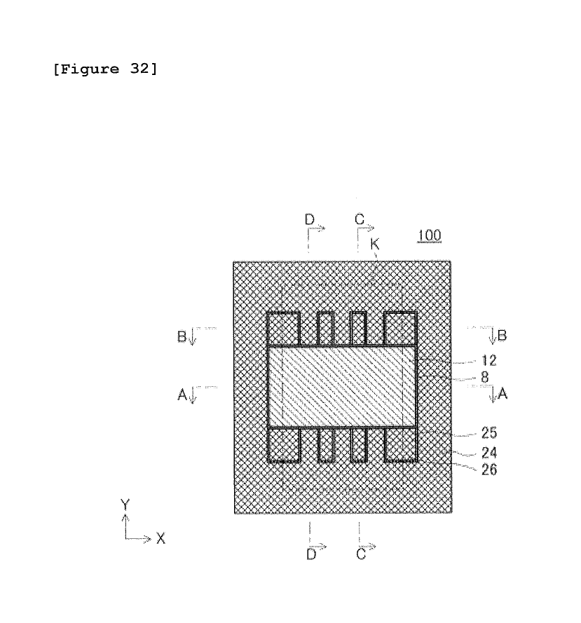

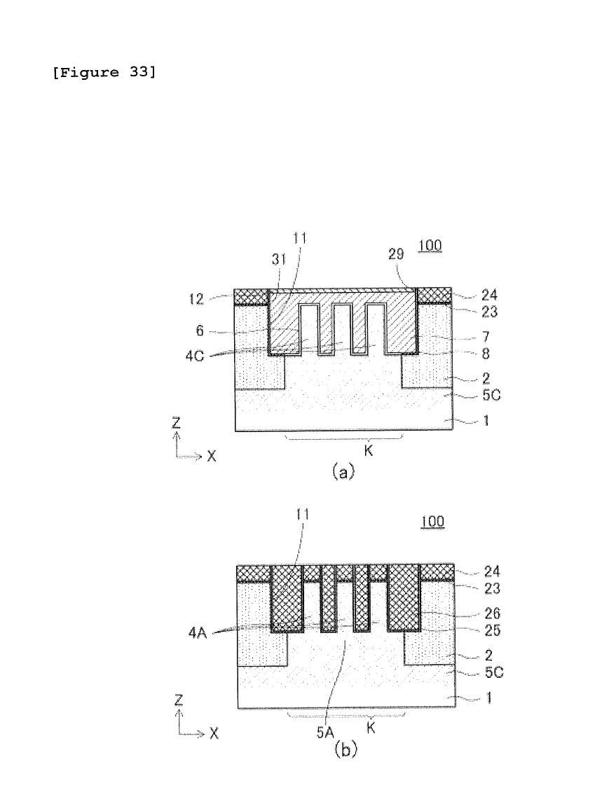

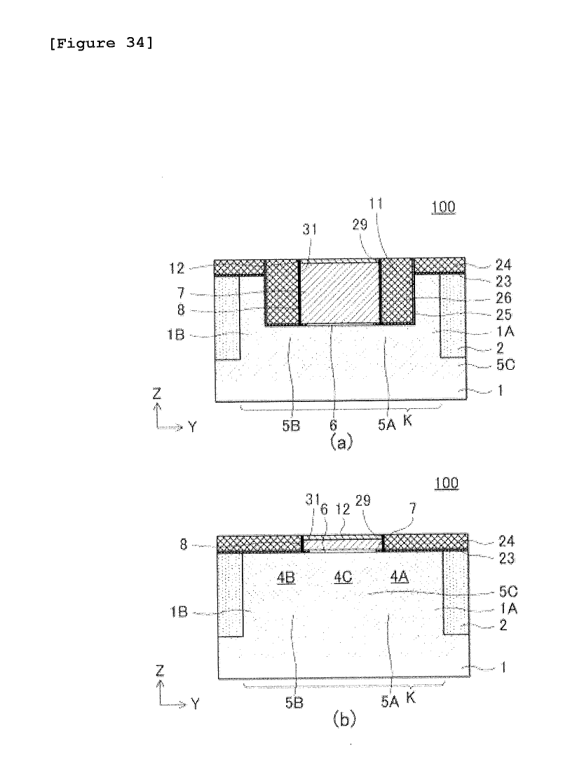

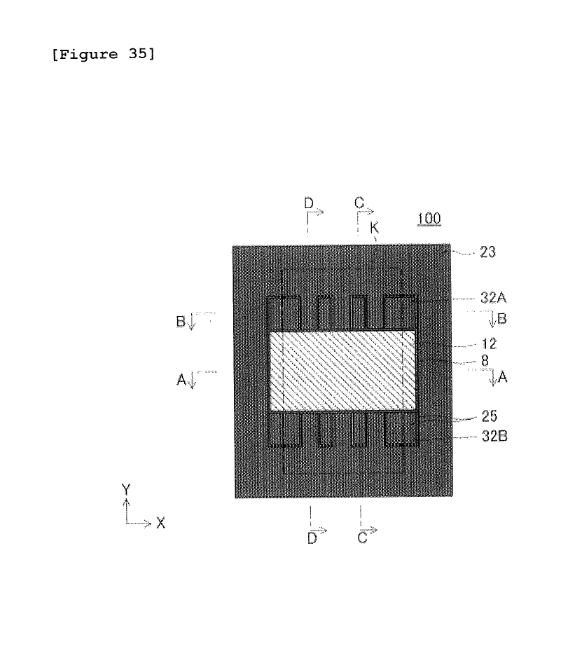

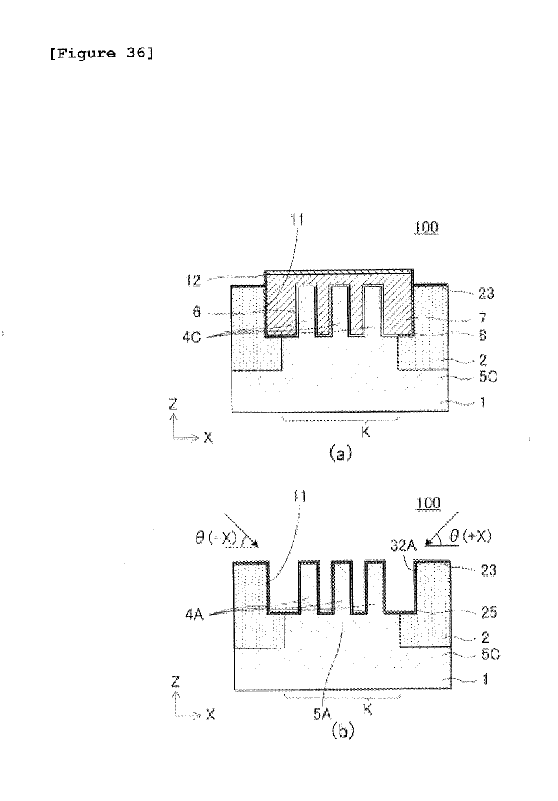

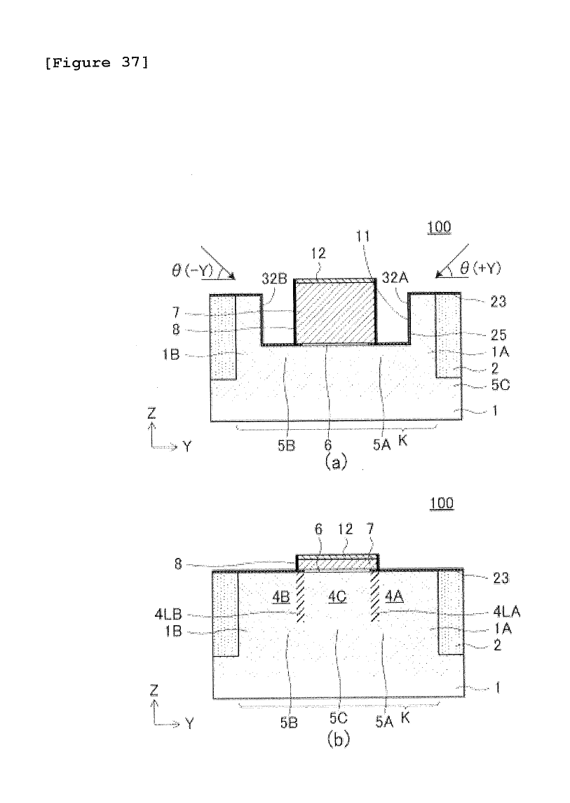

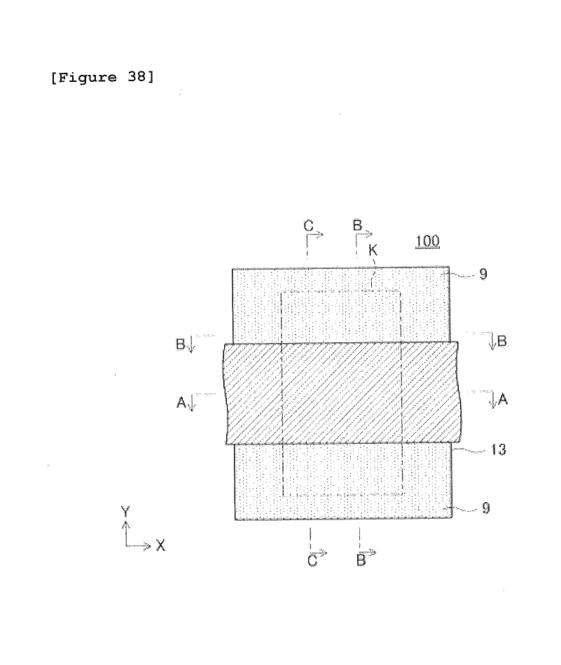

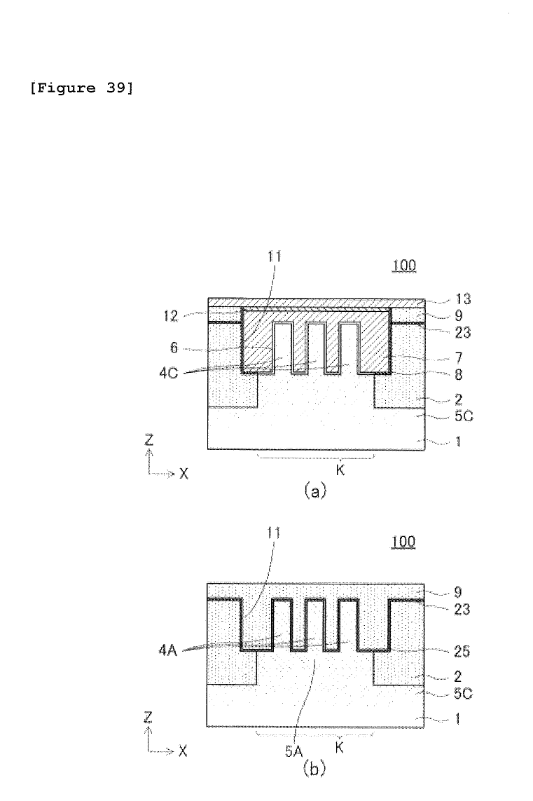

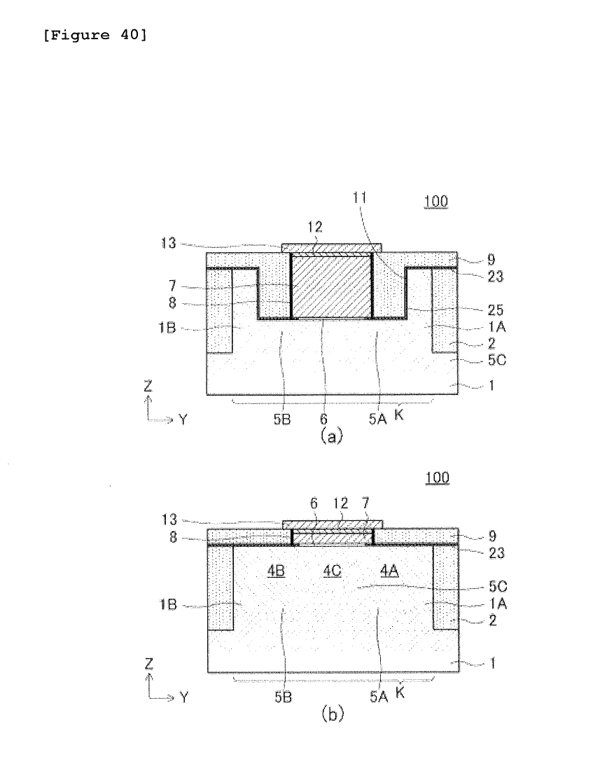

### BRIEF EXPLANATION OF THE DRAWINGS

[FIG. 1] is a plan view of a semiconductor device 100 according to a first mode of embodiment of the present invention.

[FIG. 2] (a) to (c) are respectively cross-sectional views of the semiconductor device 100 corresponding to the line A-A, the line B-B and the line C-C shown in FIG. 1.

[FIG. 3] is a drawing illustrating the upper surface of the semiconductor device 100 according to the first mode of embodiment of the present invention in the course of manufacture.

[FIG. 4] (a) to (c) are respectively cross-sectional views of the semiconductor device 100 corresponding to the line A-A, the line B-B and the line C-C shown in FIG. 3.

[FIG. 5] is a drawing illustrating the upper surface of the semiconductor device 100 according to the first mode of embodiment of the present invention in the course of manufacture.

[FIG. 6] (a) to (c) are respectively cross-sectional views of the semiconductor device 100 corresponding to the line A-A, the line B-B and the line C-C shown in FIG. 5.

[FIG. 7] is a drawing illustrating the upper surface of the semiconductor device 100 according to the first mode of embodiment of the present invention in the course of manufacture.

[FIG. 8] (a) to (c) are respectively cross-sectional views of the semiconductor device 100 corresponding to the line A-A, the line B-B and the line C-C shown in FIG. 7.

[FIG. 9] is a drawing illustrating the upper surface of the semiconductor device 100 according to the first mode of embodiment of the present invention in the course of manufacture.

[FIG. 10] (a) to (c) are respectively cross-sectional views of the semiconductor device 100 corresponding to the line A-A, the line B-B and the line C-C shown in FIG. 9.

[FIG. 11] is a drawing illustrating the upper surface of the semiconductor device 100 according to the first mode of embodiment of the present invention in the course of manufacture.

[FIG. 12] (a) to (c) are respectively cross-sectional views of the semiconductor device 100 corresponding to the line A-A, the line B-B and the line C-C shown in FIG. 11.

[FIG. 13] is a drawing illustrating the upper surface of the semiconductor device 100 according to the first mode of embodiment of the present invention in the course of manufacture.

[FIG. 14] (a) to (c) are respectively cross-sectional views of the semiconductor device 100 corresponding to the line A-A, the line B-B and the line C-C shown in FIG. 13.

[FIG. 15] is a drawing illustrating the upper surface of the semiconductor device 100 according to the first mode of embodiment of the present invention in the course of manufacture.

[FIG. 16] (a) to (c) are respectively cross-sectional views of the semiconductor device 100 corresponding to the line A-A, the line B-B and the line C-C shown in FIG. 15.

[FIG. 17] is a plan view of a semiconductor device 100 according to a second mode of embodiment of the present invention.

[FIG. 18] (a) and (b) are respectively cross-sectional views of the semiconductor device 100 corresponding to the line A-A and the line B-B shown in FIG. 17.

[FIG. 19] (a) and (b) are respectively cross-sectional views of the semiconductor device 100 corresponding to the line C-C and the line D-D shown in FIG. 17.

[FIG. 20] is a drawing illustrating the upper surface of the semiconductor device 100 according to the second mode of embodiment of the present invention in the course of manufacture.

[FIG. 21] (a) and (b) are respectively cross-sectional views of the semiconductor device 100 corresponding to the line A-A and the line B-B shown in FIG. 20.

[FIG. 22] (a) and (b) are respectively cross-sectional views of the semiconductor device 100 corresponding to the line C-C and the line D-D shown in FIG. 20.

[FIG. 23] is a drawing illustrating the upper surface of the semiconductor device 100 according to the second mode of embodiment of the present invention in the course of manufacture.

[FIG. 24] (a) and (b) are respectively cross-sectional views of the semiconductor device 100 corresponding to the line A-A and the line B-B shown in FIG. 23.

[FIG. 25] (a) and (b) are respectively cross-sectional views of the semiconductor device 100 corresponding to the line C-C and the line D-D shown in FIG. 23.

[FIG. 26] is a drawing illustrating the upper surface of the semiconductor device 100 according to the second mode of embodiment of the present invention in the course of manufacture.

[FIG. 27] (a) and (b) are respectively cross-sectional views of the semiconductor device 100 corresponding to the line A-A and the line B-B shown in FIG. 26.

[FIG. 28] (a) and (b) are respectively cross-sectional views of the semiconductor device 100 corresponding to the line C-C and the line D-D shown in FIG. 26.

[FIG. 29] is a drawing illustrating the upper surface of the semiconductor device 100 according to the second mode of embodiment of the present invention in the course of manufacture.

[FIG. 30] (a) and (b) are respectively cross-sectional views of the semiconductor device 100 corresponding to the line A-A and the line B-B shown in FIG. 29.

[FIG. 31] (a) and (b) are respectively cross-sectional views of the semiconductor device 100 corresponding to the line C-C and the line D-D shown in FIG. 29.

[FIG. 32] is a drawing illustrating the upper surface of the semiconductor device 100 according to the second mode of embodiment of the present invention in the course of manufacture.

[FIG. 33] (a) and (b) are respectively cross-sectional views of the semiconductor device 100 corresponding to the line A-A and the line B-B shown in FIG. 32.

[FIG. 34] (a) and (b) are respectively cross-sectional views of the semiconductor device 100 corresponding to the line C-C and the line D-D shown in FIG. 32.

[FIG. 35] is a drawing illustrating the upper surface of the semiconductor device 100 according to the second mode of embodiment of the present invention in the course of manufacture.

[FIG. 36] (a) and (b) are respectively cross-sectional views of the semiconductor device 100 corresponding to the line A-A and the line B-B shown in FIG. 35.

[FIG. 37] (a) and (b) are respectively cross-sectional views of the semiconductor device 100 corresponding to the line C-C and the line D-D shown in FIG. 35.

[FIG. 38] is a drawing illustrating the upper surface of the semiconductor device 100 according to the second mode of embodiment of the present invention in the course of manufacture.

[FIG. 39] (a) and (b) are respectively cross-sectional views of the semiconductor device 100 corresponding to the line A-A and the, line B-B shown in FIG. 38.

[FIG. 40] (a) and (b) are respectively cross-sectional views of the semiconductor device 100 corresponding to the line C-C and the line D-D shown in FIG. 38.

### MODES OF EMBODYING THE INVENTION

Preferred modes of embodiment of the present invention will now be described in detail with reference to the accompanying drawings.

FIG. 1 is a plan view of a semiconductor device 100 according to a first mode of embodiment of the present invention. Further, FIG. 2 (a) to (c) are respectively cross-sectional views of the semiconductor device 100 corresponding to the line A-A, the line B-B and the line C-C shown in FIG. 1. It should be noted that FIG. 1 is a cross-sectional view of the semiconductor device 100 as cut through a horizontal plane corresponding to the line D-D shown in FIG. 2 (a) to (c). However, in FIG. 1 the locations of contact plugs 14A and 14B and wiring lines 13, 15A and 15B discussed hereinafter are indicated using alternate long and short dashed lines.

As illustrated in FIG. 2 (a) to (c), the semiconductor device 100 has a semiconductor substrate 1 (a silicon substrate). An element isolation region 2 (Shallow Trench Isolation) having a depth Z2 is formed in the main surface of the semiconductor substrate 1, an active region K being demarcated thereby. The element isolation region 2 is formed by providing a trench in the semiconductor substrate 1 and filling the interior thereof with a silicon dioxide film. The planar shape of the element isolation region 2 is preferably determined in such a way that the active region K is in the shape of a rectangle that is elongated in the Y-direction (a first direction), its length in the X-direction (a second direction) being X1 and its length in the Y-direction being Y1 (>X1), as illustrated in FIG. 1.

A trench 11 is provided in the surface of the semiconductor substrate 1. As illustrated in FIG. 1, the trench 11 is provided in a region overlapping respectively the active region K and the element isolation region 2 as seen in a plan view. To explain this more specifically, the length X2 of the trench 11 in the X-direction is greater than the abovementioned length X1, and therefore the planar region in which the trench 11 is formed overlaps the element isolation region 2 on both sides in the X-direction. On the other hand, the length Y2 of the trench 11 in the Y-direction is less than the abovementioned length Y1, and therefore regions in which the trench is not present remain at both ends of the active region K in the Y-direction. Hereinafter, in these remaining regions, a section located at one end in the Y-direction is referred to as a first substrate region 1A, and a section located at one end in the Y-direction is referred to as a second substrate region 1B.

Three semiconductor beams 4 disposed at equal intervals in the X-direction are erected on the bottom surface of the trench 11, each extending in the Y-direction. The upper surface of each semiconductor beam 4 is located at the same height as the element isolation region 2 and the active region K. Further, each semiconductor beam 4 is connected respectively at one end of the trench 11 in the Y-direction to the first substrate region 1A and at the other end to the second substrate region 1B. Four trenches 11A to 11D are formed in the interior of the trench 11 by providing the semiconductor beams 4.

As illustrated in FIG. 2 (a), sections in which the element isolation region 2 is exposed, and sections in which the semiconductor substrate 1 is exposed coexist on the inner surfaces of the outermost of the trenches 11A to 11D, namely the two trenches 11A and 11D. In contrast, only the semiconductor substrate 1 is exposed on the inner surfaces of the other trenches 11B and 11C.

As illustrated in FIG. 2 (b), (c), the first substrate region 1A from a location at a depth Z3 (<Z2) as far as the upper surface of the semiconductor substrate 1 comprises a dopant-diffused layer 5A (a first dopant-diffused layer) in which a dopant has been diffused. Similarly, the second substrate region 1B from a location at the depth Z3 as far as the upper surface of the semiconductor substrate 1 comprises a dopant-diffused layer 5B (a second dopant-diffused layer) in which a dopant has been diffused. Therefore one end of each semiconductor beam 4 is connected to the dopant-diffused layer 5A and the other end is connected to the dopant-diffused layer 5B. It should be noted that the reason that the dopant-diffused layers 5A and 5B are formed only in sections shallower than a location at a depth Z2 (the bottom surface of the element isolation region 2) is in order to achieve, by means of the element isolation region 2, insulation with respect to dopant-diffused layers 5A, 5B within adjacent active regions K which are not shown in the drawings. The same conduction-type (p-type or n-type) dopant is introduced into both of the dopant-diffused layers 5A, 5B.

The region of the semiconductor substrate 1 from a location at the depth Z1 (>Z2) as far as the upper surface of the semiconductor substrate 1, excluding the regions comprising the dopant-diffused layers 5A, 5B, comprises a dopant-diffused layer 5C in which a dopant has been diffused. Therefore the surface of each semiconductor beam 4 and the bottom surfaces of the trenches 11A to 11D each comprise the dopant-diffused layer 5C, the dopant-diffused layer 5C within the active region K being integrated. Further, the dopant-diffused layer 5C is also formed below the element isolation region 2. A conduction-type dopant that differs from that in the dopant-diffused layers 5A, 5B is introduced into the dopant-diffused layer 5C.

A gate insulating film 6 covers the inner surface of the trench 11, including the side surfaces of each semiconductor beam 4, and the upper surfaces of each semiconductor beam 4. It should be noted that the sections of this gate insulating film 6 that are in contact with the element isolation region 2 and the dopant-diffused layers 5A, 5B do not function as gate insulating films, and therefore they are hereinafter referred to simply as ‘insulating films 8’, without the word ‘gate’.

The interior of the trench 11 is filled, on top of the gate insulating film 6 and the insulating film 8, with a gate electrode 7 comprising a laminated film (gate electrode material) of tungsten and titanium nitride. As illustrated for example in FIG. 2 (a), the gate electrode 7 is formed up to a location that is higher than the upper surface of the semiconductor beams 4, and is formed over the whole of the region corresponding to the inside of the trench 11 as seen in a plan view. Therefore the gate electrode 7 covers the inner surface of the trench 11, including the side surfaces of each semiconductor beam 4, and the upper surface of each semiconductor beam 4, with the interposition of the gate insulating film 6 and the insulating film 8. Further, the gate electrode 7 formed in the interior of the active region K is integrated, forming a single gate electrode 7.

By means of the construction described hereinabove, one MOS transistor (fin-type FET) is configured in the active region K, the gate electrode 7 serving as a gate, one of the dopant-diffused layers 5A, 5B serving as a source, and the other serving as a drain. The dopant-diffused layer 5C sandwiched between the dopant-diffused layer 5A and the dopant-diffused layer 5B constitutes the channel region of this MOS transistor.

It should be noted that in the semiconductor device 100, three semiconductor beams 4 are provided within the trench 11, but the scope of application of the present invention is not limited to this number. The present invention can be suitably applied in general to fin-type semiconductor devices in which one or more semiconductor beams 4 is provided within the trench 11.

A conductive film 12 is formed on the upper surface of the gate electrode 7. The conductive film 12 is formed by means of a polysilicon film in which a conduction-type dopant that is the same as the dopant diffused in the dopant-diffused layers 5A, 5B has been diffused. Further, an interlayer insulating film 9 comprising a silicon dioxide film is formed on the regions of the respective upper surfaces of the active region K and the element isolation region 2 that do not overlap the gate electrode 7 as seen in a plan view. The upper surface of the interlayer insulating film 9 is located at the same height as the upper surface of the conductive film 12.

A wiring line 13 extending in the X-direction is disposed on the upper surface of the conductive film 12 and the interlayer insulating film 9. Supply of power to the gate electrode 7 is effected via the wiring line 13. The length of the wiring line 13 in the Y-direction is set such that it is similar to the length of the semiconductor beams 4 in the Y-direction.

An interlayer insulating film 16 comprising a silicon dioxide film is provided on the upper surface of the interlayer insulating film 9 to a film thickness such that it covers the wiring line 13. Wiring lines 15A, 15B, each extending in the X-direction, are disposed on the upper surface of the interlayer insulating film 16. The wiring line 15A is formed above the first substrate region 1A, and is connected to the first substrate region 1A (the dopant-diffused layer 5A) by means of contact plugs 14A which penetrate through the interlayer insulating films 9, 16. Meanwhile, the wiring line 15B is formed above the second substrate region 1B, and is connected to the second substrate region 1B (the dopant-diffused layer 5B) by means of contact plugs 14B which penetrate through the interlayer insulating films 9, 16. As illustrated in FIG. 1, three each of the contact plugs 14A, 14B are disposed in the X-direction.

The operation of the semiconductor device 100 having the configuration described hereinabove will now be described. When the wiring line 13 is activated, the gate electrode 7 is activated via the conductive film 12, and a channel is formed in the dopant-diffused layer 5C. In other words, the MOS transistor configured within the active region K is turned on. This channel causes the dopant-diffused layer 5A and the dopant-diffused layer 5B to conduct, giving rise to a state in which the wiring lines 15A and 15B are electrically connected to each other. On the other hand, when the wiring line 13 is in an inactive state, the gate electrode 7 becomes inactive, via the conductive film 12, and the channel within the dopant-diffused layer 5C disappears. In other words, the MOS transistor configured within the active region K is turned off. In this case, the dopant-diffused layer 5A and the dopant-diffused layer 5B are electrically isolated from each other, and thus the wiring lines 15A and 15B are also electrically isolated from each other.

According to the semiconductor device 100 of the present mode of embodiment, as described in detail hereinafter it is possible to form the gate electrode 7 by dry etching only sections of the gate electrode material that have been formed to a given film thickness. Damage to the semiconductor beams 4 or the semiconductor substrate 1 caused by dry etching of the gate electrode material when the semiconductor device 100 is being manufactured can therefore be significantly suppressed compared with the background art discussed hereinabove.

Further, the side surfaces and the upper surface of each semiconductor beam 4, and the bottom surfaces of the trenches 11A to 11D (the sections other than the sections in which the element isolation region 2 is exposed) can be used as a channel region, and therefore the effective channel width can be increased compared with a case in which a planar MOS transistor occupying the same surface area is produced. The electrical driving force is thus increased and the channel-potential controllability improves, and it is therefore possible to avoid degradation of the element characteristics resulting from the short channel effect, which has been a problem with planar MOS transistors, without increasing the dopant concentration within the channel.

A method of manufacturing the semiconductor device 100 according to the present mode of embodiment will now be described with reference to the drawings.

FIG. 3 to FIG. 16 are each drawings illustrating the semiconductor device 100 in the course of manufacture. Of these, FIG. 3, FIG. 5, FIG. 7, FIG. 9, FIG. 11, FIG. 13 and FIG. 15 each illustrate the upper surface of the semiconductor device 100. Further, (a) to (c) in FIG. 4, FIG. 6, FIG. 8, FIG. 10, FIG. 12, FIG. 14 and FIG. 16 are cross-sectional views of the semiconductor device 100, corresponding respectively to the line A-A, the line B-B and the line C-C shown in FIG. 3, FIG. 5, FIG. 7, FIG. 9, FIG. 11, FIG. 13 and FIG. 15.

In this method of manufacture, first the semiconductor substrate 1 is prepared, and as illustrated in FIG. 3 and FIG. 4, the dopant-diffused layer 5C is formed by implanting boron (B) into the surface of the semiconductor substrate 1 using an ion implantation method. Here, the boron implantation is preferably performed by three-stage implantation. In this case, preferably the first stage implantation conditions are an implantation energy of 150 keV and a dosage of 1×10¹³ atoms/cm², the second stage implantation conditions are an implantation energy of 100 keV and a dosage of 5×10¹² atoms/cm², and the third stage implantation conditions are an implantation energy of 50 keV and a dosage of 3×10¹² atoms/cm². The concentration of the boron implanted using this method has a distribution having three peaks in the depth direction (the Z-direction) of the semiconductor substrate 1, but by thermally diffusing the boron to a depth of 300 nm (=Z1) by heat-treating the semiconductor substrate 1 for 30 minutes in an oxygen atmosphere at 900° C., the concentration is homogenized to 1×10¹⁷ atoms/cm³. By means of this heat-treatment, an insulating film (which is not shown in the drawings), being a silicon dioxide (SiO₂) film of thickness 10 nm, is formed on the surface of the semiconductor substrate 1.

Next, using a CVD (Chemical Vapor Deposition) method, a masking film 21, being a silicon nitride (SiN) film having a film thickness of 50 nm, is formed on the upper surface of the silicon dioxide film which is not shown in the drawings discussed hereinabove. Then, after the masking film 21 in the region in which the element isolation region 2 is to be formed has been removed using a photolithographic method, dry etching is performed, using the remaining masking film 21 as a mask, to form a trench 10 demarcating the active region K. By forming the trench 10, an island-shaped dopant-diffused layer 5C having a length X1 in the X-direction and a length Y1 in the Y-direction is formed on the surface of the semiconductor substrate 1, as illustrated in FIG. 3. It should be noted that preferably X1 is 210 nm and Y1 is 420 nm. Further, the height Z2 (=the depth of the trench 10) of the island-shaped dopant-diffused layer 5C is preferably 200 nm, which is less than the height Z1 of the dopant-diffused layer 5C. By this means the dopant-diffused layer 5C also remains at the bottom surface of the trench 10. The film thickness of the masking film 21 after dry etching is approximately 30 nm.

Next, a silicon dioxide film is deposited using a CVD method to a film thickness whereby the trench 10 is filled (300 nm), after which the silicon dioxide film that has been deposited on the upper surface of the masking film 21 is removed using a CMP (Chemical Mechanical Polishing) method. Then a 30 nm-thick portion (equivalent to the height of the masking film 21) of the upper portion of the silicon dioxide film that has been formed in the interior of the trench 10 is removed using an etch-back method, after which the remaining masking film 21 is removed using a wet etching method. By this means the trench 10 is filled, and an element isolation region 2 demarcating the active region K is formed, as illustrated in FIG. 5 and FIG. 6. The height of the upper surface of the element isolation region 2 formed in this way coincides with the height of the upper surface of the semiconductor substrate 1.

Next, as illustrated in FIG. 7 and FIG. 8, a photoresist 22 is applied to the upper surface of the semiconductor substrate 1, and open portions 22A, 22B are provided in locations corresponding respectively to the two end portions of the active region K in the Y-direction by means of a photolithographic method. The gap between the open portions 22A, 22B in the Y-direction is the length Y2 in the Y-direction of the trench 11 discussed hereinabove. The first and second substrate regions 1A, 1B discussed hereinabove are respectively exposed on the bottom surfaces of the open portions 22A, 22B formed in this way.

Next, arsenic (As) is implanted into the first and second substrate regions 1A, 1B via the open portions 22A, 22B using an ion implantation method. By this means dopant-diffused layers 5A, 5B are formed respectively in the first and second substrate regions 1A, 1B. Preferably this arsenic implantation is performed under implantation conditions in which the implantation energy is 20 keV and the dosage is 5×10¹⁵ atoms/cm², the arsenic being thermally diffused, after implantation, to a depth of 110 nm (=Z3) by heat-treating the semiconductor substrate 1 for 30 minutes at 900° C. to yield a concentration of 1×10²⁰ atoms/cm³.

The photoresist 22 is removed when formation of the dopant-diffused layers 5A, 5B is complete, after which a protective film 23, being a silicon dioxide film having a thickness of 10 nm, and a masking film 24 (a first masking film), being a silicon nitride film having a thickness of 100 nm, are formed in succession on the upper surface of the semiconductor substrate 1 using a CVD method. A photolithographic method and a dry etching method are then used to process the masking film 24 into the pattern of the trenches 11A to 11D discussed hereinabove, and then dry etching is performed using the masking film 24 as a mask to form the trenches 11A to 11D illustrated in FIG. 9 and FIG. 10. The length X3 of the trenches 11A, 11D in the X-direction, the length X4 of the trenches 11B, 11C in the X-direction, and the gap X5, the length Y2 in the Y-direction, and the depth Z4 of the trenches 11A to 11D are preferably 60 nm, 30 nm, 30 nm, 270 nm and 100 nm respectively. Here, the length X1 (FIG. 3) of the active region K in the X-direction is set to 210 nm, and therefore the trenches 11A, 11D each extend out 30 nm from the active region K in the X-direction, on the element isolation region 2 side. Forming the trenches 11A to 11D completes the trench 11 on the bottom surface of which three semiconductor beams 4 have been erected.

Next the protective film 23 and the masking film 24 are removed using a wet etching method, to expose the respective upper surfaces of the semiconductor beams 4, the first and second substrate regions 1A, 1B and the element isolation region 2. A silicon dioxide film having a thickness of 1.5 nm is then formed over the entire surface using a CVD method, and further a silicon dioxide film having a thickness of 2 nm is formed using a thermal oxidation method. As illustrated in FIG. 12, in the silicon dioxide film formed at this time, the sections formed on the surface of the dopant-diffused layer 5C (the side surfaces and the upper surface of each semiconductor beam 4, and the respective bottom surfaces of the trenches 11A to 11D) comprise the gate insulating film 6, and sections formed on other surfaces comprise the insulating film 8. It should be noted that the thermal oxidation conditions are preferably a heating temperature of 900° C., a heating time of 20 seconds, in an oxygen atmosphere.

A gate electrode material which will form the gate electrode 7 is next deposited to a film thickness whereby the trench 11 is filled. More specifically, titanium nitride (TiN) having a thickness of 5 nm is formed over the entire surface using a CVD method, and further, tungsten (W) having a thickness of 60 nm is deposited over the entire surface using a CVD method. As illustrated in FIG. 11 and FIG. 12, the gate electrode material deposited in this way fills the entire trench 11, and is also formed on the upper surfaces of the semiconductor beams 4, the first and second substrate regions 1A, 1B and the element isolation region 2.

Next, a masking film (a second masking film; not shown in the drawings) which covers a region corresponding to the inside of the trench 11 as seen in a plan view is formed by photolithography, and this is used as a mask for dry etching performed to remove the gate electrode material located outside the trench 11 as seen in a plan view, as illustrated in FIG. 13 and FIG. 14. In the present mode of embodiment the insulating film 8 located outside the trench 11 as seen in a plan view is also removed at this time. By this means the upper surfaces of the first and second substrate regions 1A, 1B and the element isolation region 2 are exposed, and a gate electrode 7 is formed in a region corresponding to the inside of the trench 11.

Here, the gate electrode material which is subjected to dry etching in this step is only the section located outside the trench 11 as seen in a plan view (only the section deposited above the first and second substrate regions 1A, 1B and the element isolation region 2). The film thickness of the gate electrode material in this section is constant, and therefore damage to the semiconductor beams 4 and the semiconductor substrate 1 resulting from the dry etching of the gate electrode material is significantly suppressed compared with the background art discussed hereinabove.

Next, an ion implantation method is used to implant arsenic into regions within the dopant-diffused layers 5A, 5B (the first and second substrate regions 1A, 1B) in particular in the vicinity of the semiconductor beams 4 and the trenches 11A to 11D, and further, the implanted arsenic is caused to diffuse into each semiconductor beam 4 by thermal diffusion. By this means, as illustrated in FIG. 14 (c) lightly doped region layers (Lightly Doped Drains) 4LA, 4LB are formed respectively at the two ends in the Y-direction of each semiconductor beam 4. It should be noted that depictions of the lightly doped region layers 4LA, 4LB are omitted from the other drawings (for example FIG. 2 and FIG. 16 described hereinafter). This arsenic implantation is preferably performed under implantation conditions in which the implantation energy is 40 keV and the dosage is 5×10¹⁴ atoms/cm². Further, implantation is preferably performed from both sides in the Y-direction (represented by ‘+Y’ and ‘−Y’ in FIG. 14 (b), (c).) toward the active region K at a prescribed angle θ (the angle relative to the main surface of the semiconductor substrate 1). Further, it is preferable to employ heat-treatment at 1000° C. for 10 seconds as the thermal diffusion after implantation. By forming the lightly doped region layers 4LA, 4LB, the electric field at the drain end is alleviated, and the short channel effect is suppressed.

Next, a silicon dioxide film having a thickness of 100 nm is deposited over the entire surface using a CVD method, and further, by effecting planarization using a CMP method, this silicon dioxide film is removed to the extent that the upper surface of the gate electrode 7 is exposed. By this means, as illustrated in FIG. 15 and FIG. 16, the interlayer insulating film 9 covering the upper surfaces of the first and second substrate regions 1A, 1B and the element isolation region 2 is formed.

Next, the upper surface of the gate electrode 7 is excavated to a thickness of 10 nm by etch-back using dry etching. Because this dry etching only shaves a little from the upper surface of the gate electrode 7, it does not damage the underlying material. By this means a recessed portion 29 having a depth of 10 nm is formed, the side surfaces thereof comprising the interlayer insulating film 9 and the bottom surface comprising the gate electrode 7, as illustrated in FIG. 16. A polysilicon film (polycrystalline silicon film) is then deposited over the entire surface to a film thickness whereby the recessed portion 29 is filled, and by removing the polysilicon film remaining on the upper surface of the interlayer insulating film 9 using a CMP method, a conductive film 12 filling the recessed portion 29 is formed. The lower surface of the conductive film 12 formed in this way is connected to the upper surface of the gate electrode 7.

Next, after depositing tungsten having a thickness of 50 nm over the entire surface using a CVD method, the tungsten is processed into the shape of a wiring line 13 by means of a photolithographic method and a dry etching method. As discussed hereinabove, the wiring line 13 extends in the X-direction and is in contact at its lower surface with the conductive film 12.

Next, as illustrated in FIG. 2, the interlayer insulating film 16, being a silicon dioxide film having a thickness of 200 nm, is formed using a CVD method, after which the upper surface of the interlayer insulating film 16 is planarized using a CMP method. Then through-holes penetrating through the interlayer insulating films 16, 9 are formed in three locations above each of the first and second substrate regions 1A, 1B by means of a photolithographic method and a dry etching method. The dopant-diffused layers 5A, 5B are exposed on the bottom surfaces of the through-holes formed in this way. Next, titanium nitride (TiN) having a thickness of 5 nm is deposited over the entire surface using a CVD method, after which tungsten (W) is further deposited using a CVD method to a film thickness whereby the abovementioned through-holes are filled, and then by using a CMP method to remove the films that have been formed outside the through-holes, the contact plugs 14A, 14B are formed. It should be noted that the planar shape of the contact plugs 14A, 14B is preferably a square of side 30 nm.

After the contact plugs 14A, 14B have been formed, tungsten nitride (WN) and tungsten (W) are successively laminated onto the upper surface of the interlayer insulating film 16 using a sputtering method, and these are processed to form the wiring lines 15A, 15B by means of a photolithographic method and a dry etching method. It should be noted that the wiring line 15A is formed in such a way that it covers the contact plugs 14A, and the wiring line 15B is formed in such a way that it covers the contact plugs 14B. By this means the wiring lines 15A, 15B are respectively connected via the contact plugs 14A, 14B to the dopant-diffused layers 5A, 5B.

As explained hereinabove, according to this method of manufacture, only sections of the gate electrode material that have been formed to a given film thickness are subjected to dry etching. Damage to the semiconductor beams 4 or the semiconductor substrate 1 resulting from the dry etching of the gate electrode material is therefore significantly suppressed compared with the background art discussed hereinabove.

FIG. 17 is a plan view of a semiconductor device 100 according to a second mode of embodiment of the present invention. Further, FIG. 18 (a) and (b) and FIG. 19 (a) and (b) are respectively cross-sectional views of the semiconductor device 100 corresponding to the line A-A, the line B-B, the line C-C and the line D-D shown in FIG. 17. It should be noted that FIG. 17 is a cross-sectional view of the semiconductor device 100 as cut through a horizontal plane corresponding to the line E-E shown in FIG. 18 (a) and (b) and FIG. 19 (a) and (b). In FIG. 17, the locations of contact plugs 14A and 14B and wiring lines 13, 15A and 15B are indicated using alternate long and short dashed lines in the same way as in FIG. 1.

The semiconductor device 100 according to the present mode of embodiment differs in that the sections of the gate electrode 7 that were formed in sections overlapping the two end portions in the Y-direction of the trench 11 as seen in a plan view have been replaced with the interlayer insulating film 9, and in that the dopant-diffused layers 5A, 5B have also been provided in the interior of each semiconductor beam 4. There are also differences in the places in which the insulating film 8 remains, and in that the protective film 23 remains, but these result from changes to the manufacturing processes concomitant with the abovementioned two differences. An explanation focusing on the points of difference will now be provided.

First, with regard to the dopant-diffused layers 5A, 5B, in the present mode of embodiment the dopant-diffused layers 5A, 5B are also provided in the interior of each semiconductor beam 4, as illustrated in FIG. 17 to FIG. 19. To explain this more specifically, in addition to being formed within the first substrate region 1A, the dopant-diffused layer 5A is also formed in the end portion of each semiconductor beam 4 close to the first substrate region 1A. Further, in addition to being formed within the second substrate region 1B, the dopant-diffused layer 5B is also formed in the end portion of each semiconductor beam 4 close to the second substrate region 1B. In some cases hereinafter, the sections of each semiconductor beam 4 comprising the dopant-diffused layer 5A are referred to as semiconductor beams 4A, the sections comprising the dopant-diffused layer 5B are referred to as semiconductor beams 4B, and other sections (the sections comprising the dopant-diffused layer 5C) are referred to as semiconductor beams 4C. The semiconductor beams 4C are sandwiched between the semiconductor beams 4A and the semiconductor beams 4B.

Next, regarding the gate electrode 7 according to the present mode of embodiment, as illustrated in FIG. 17 to FIG. 19, the interlayer insulating film 9 rather than the gate electrode 7 is formed in regions overlapping the two ends in the Y-direction of the trench 11 as seen in a plan view. The interlayer insulating film 9 is the same as that described in the first mode of embodiment, but in the present mode of embodiment, in addition to being formed for example on the upper surface of the element isolation region 2, the interlayer insulating film 9 is also formed between the gate electrode 7 and the insulating film 8 formed on the surface that constitutes the respective side surfaces of the first and second substrate regions 1A, 1B, on the inner surface of the trench 11. As a result, the gate electrode 7 is formed only in a region overlapping the central portion in the Y-direction of the trench 11 as seen in a plan view.

As illustrated in FIG. 19(b), the length Y4 of the gate electrode 7 in the Y-direction is set to be slightly longer than the length Y3 of the semiconductor beam 4C in the Y-direction. Therefore the side surfaces and the upper surface of the semiconductor beam 4C are entirely covered by the gate electrode 7, with the interposition of the gate insulating film 6. On the other hand, the side surfaces and the upper surfaces of the semiconductor beams 4A, 4B are covered by the gate electrode 7, with the interposition of the gate insulating film 6, only in one section close to the semiconductor beam 4C, other sections being covered by the interlayer insulating film 9, with the interposition of the insulating film 8.

According to the semiconductor device 100 of the present mode of embodiment, as described in detail hereinafter it is possible to form the gate electrode 7 using a CMP method rather than by dry etching. There is therefore no damage to the semiconductor beams 4 or the semiconductor substrate 1 caused by dry etching of the gate electrode material when the semiconductor device 100 is being manufactured.

Further, the side surfaces and the upper surface of each semiconductor beam 4C, and the corresponding bottom surfaces of the trenches 11A to 11D (the sections other than the sections in which the element isolation region 2 is exposed) can be used as a channel region, and therefore the effective channel width can be increased compared with a case in which a planar MOS transistor occupying the same surface area is produced. The electrical driving force is thus increased and the channel-potential controllability improves, and it is therefore possible to avoid degradation of the element characteristics resulting from the short channel effect, which has been a problem with planar MOS transistors, without increasing the dopant concentration within the channel.

It should be noted that, as discussed hereinafter, the process for manufacturing the semiconductor device 100 according to the present mode of embodiment includes a step in which, after the interior of the trenches 11A to 11D has been filled with an insulating film 26, the insulating film 26 located in sections in which the gate electrode 7 is to be formed is removed using a photolithographic method and a dry etching method. The gate electrode 7 is formed by filling the sections in which the insulating film 26 has been removed with a gate electrode material, but there is a possibility that the etching location may deviate in the Y-direction when the insulating film 26 is being etched. However, according to the semiconductor device 100 of the present mode of embodiment, even if for sake of argument the etching location of the insulating film 26 were to deviate in the Y-direction, the interlayer insulating film 9 which subsequently replaces the insulating film 26 would serve as a buffer region, and it is therefore possible to prevent degradation of the element characteristics resulting from this positional deviation.

A method of manufacturing the semiconductor device 100 according to the present mode of embodiment will now be described with reference to the drawings.

FIG. 20 to FIG. 40 are each drawings illustrating the semiconductor device 100 in the course of manufacture. Of these, FIG. 20, FIG. 23, FIG. 26, FIG. 29, FIG. 32, FIG. 35 and FIG. 38 each illustrate the upper surface of the semiconductor device 100. Further, (a) and (b) in FIG. 21, FIG. 24, FIG. 27, FIG. 30, FIG. 33, FIG. 35 and FIG. 39 are cross-sectional views of the semiconductor device 100, corresponding respectively to the line A-A and the line B-B shown in FIG. 20, FIG. 23, FIG. 26, FIG. 29, FIG. 32, FIG. 35 and FIG. 38. Further, (a) and (b) in FIG. 22, FIG. 25, FIG. 28, FIG. 31, FIG. 34, FIG. 36 and FIG. 40 are cross-sectional views of the semiconductor device 100, corresponding respectively to the lines C-C and D-D shown in FIG. 20, FIG. 23, FIG. 26, FIG. 29, FIG. 32, FIG. 35 and FIG. 38.

In this method of manufacture also, first the dopant-diffused layer 5C, the element isolation region 2 and the active region K are formed on the surface of the semiconductor substrate 1. The steps up to this point are the same as were described for the first mode of embodiment with reference to FIG. 3 to FIG. 6, and so a detailed description thereof is omitted.

Next, as illustrated in FIG. 20 to FIG. 22, the photoresist 22 is applied to the upper surface of the semiconductor substrate 1, and the open portions 22A, 22B are provided in locations corresponding respectively to the two end portions of the active region K in the Y-direction by means of a photolithographic method. The gap in the Y-direction between the open portions 22A, 22B is the same as the length Y4 in the Y-direction of the gate electrode 7 discussed hereinabove, this being shorter than the gap Y2 in the Y-direction between the open portions 22A, 22B in the first mode of embodiment. Next, arsenic (As) is implanted into the semiconductor substrate 1 via the open portions 22A, 22B using an ion implantation method. By this means the dopant-diffused layers 5A, 5B are formed in the surface of the semiconductor substrate 1. The arsenic implantation conditions employed here should be the same as those employed when the dopant-diffused layers 5A, 5B were formed in the first mode of embodiment.

Next, as illustrated in FIG. 23 to FIG. 25, a protective film 23 and a masking film 24 (a first masking film) that are the same as those described in the first mode of embodiment are formed successively, to form the trenches 11A to 11D. The specific method of forming the trenches 11A to 11D should be the same as that described for the first mode of embodiment with reference to FIG. 9 and FIG. 10, and this completes the trench 11 on the bottom surface of which the three semiconductor beams 4 have been erected.

After the trenches 11A to 11D have been formed, a protective film 25, being a silicon dioxide film having a thickness of 10 nm, and the masking film 26 (fourth masking film), being a silicon nitride film having a thickness of 70 nm, are deposited successively using a CVD method. Then, the protective film 25 and the insulating film 26 remaining on the upper surface of the masking film 24 are removed using a CMP method, the protective film 25 and the insulating film 26 remaining only in the interior of the trenches 11A to 11D. It should be noted that the film thickness of the masking film 24 remaining after removal using the CMP method at this time is approximately 80 nm, which is approximately 20 nm less than when it was first deposited.

Next, a multilayer masking film 27 is applied over the entire surface, and as illustrated in FIG. 26 to FIG. 28 the pattern of the sections of the trenches 11A to 11D that are to be filled with the gate electrode 7 is transferred using a photolithographic method. Then, using this as a mask for dry etching to remove the insulating film 26, trenches 28 are formed. By forming these trenches 28, the insulating film 26 becomes a masking film filling both end portions in the Y-direction of the trenches 11A to 11D. It should be noted that the multilayer masking film 27 preferably comprises a lower layer masking film, being a BARC (Bottom Anti-Reflective Coating; anti-reflection film), an intermediate masking film, being a BARC containing silicon, and an upper layer masking film, being a photoresist, each of these being polymers.

Here, the dry etching employed when the trenches 28 are formed is performed under conditions such that the silicon nitride film is selectively removed. By this means, while the dry etching is being performed, the protective film 25 remains on the inner surfaces of the trenches 11A to 11D. Further, the film thickness of the insulating film 26 subjected to removal by dry etching is constant. There is therefore almost no risk that the semiconductor substrate 1 exposed on the inner surfaces of the trenches 11A to 11D will be damaged by the dry etching. Further, a trench 31 is formed using wet etching, and thus the risk that this will damage the semiconductor substrate 1 is also small. It may therefore be assumed that there is almost no risk that the dry etching effected here will damage the semiconductor substrate 1.

When the trenches 28 have been formed, the multilayer masking film 27 is removed, after which a resist mask 30 is applied, and the pattern of the gate electrode 7 is transferred using a photolithographic method as illustrated in FIG. 29 to FIG. 31. By this means a region corresponding to the outside of the trench 11 as seen in a plan view is covered, and the resist mask 30 (the third masking film) having an open portion 30a exposing at least a portion (the central section in the Y-direction) of a region corresponding to the inside of the trench 11 as seen in a plan view is formed. Then, using this as a mask for wet etching, the trench 31 is formed by removing the protective film 23 and the masking film 24 formed on the upper surfaces of each semiconductor beam 4, and the protective film 25 remaining on the inner surfaces of the trenches 11A to 11D.

A silicon dioxide film having a thickness of 1.5 nm is then formed over the entire surface using a CVD method, after which a silicon dioxide film having a thickness of 2 nm is formed using a thermal oxidation method on the inner surface of the trench 31, including the upper surfaces and the side surfaces of each semiconductor beam 4. As illustrated in FIG. 33 and FIG. 34, in the silicon dioxide film formed at this time, the sections formed on the surface of the dopant-diffused layer 5C comprise the gate insulating film 6, and sections formed on other surfaces comprise the insulating film 8.

A gate electrode material which will form the gate electrode 7 is next deposited to a film thickness whereby the trench 31 is filled. More specifically, titanium nitride (TiN) having a thickness of 5 nm is formed over the entire surface using a CVD method, and further, tungsten (W) having a thickness of 60 nm is deposited over the entire surface using a CVD method. The tungsten and the titanium nitride are then removed using a CMP method until the masking film 24 is exposed. The gate electrode 7 is formed by this means in the interior of the trench 31, as illustrated in FIG. 32 to FIG. 34.

In this way, in the present mode of embodiment the gate electrode 7 can be formed by grinding the gate electrode material using a CMP method. In the present mode of embodiment there is therefore no damage to the semiconductor beams 4 or the semiconductor substrate 1 resulting from dry etching of the gate electrode material.

Next, the upper surface of the gate electrode 7 is excavated to a thickness of 10 nm by etch-back using dry etching. Because this dry etching only shaves a little from the upper surface of the gate electrode 7, it does not damage the underlying material. By this means the gate electrode 7 is formed covering the interior of the trench 31, with the interposition of the gate insulating film 6 or the insulating film 8, and the recessed portion 29 surrounded by the insulating film 8 and the gate electrode 7 is formed in the upper portion of the trench 31. It should be noted that the depth of the recessed portion 29, namely 10 nm, is determined in such a way that the bottom surface of the recessed portion 29 is located above the upper surface of the gate insulating film 6 formed on the upper surface of the semiconductor beams 4C.

A polysilicon film (polycrystalline silicon film) is then deposited over the entire surface using a CVD method to a film thickness whereby the recessed portion 29 is filled, and the sections formed outside the recessed portion 29 as seen in a plan view are removed using a CMP method. By this means the interior of the recessed portion 29 is filled with the conductive film 12, which is a polysilicon film.

Next, the masking film 24 and the insulating film 26 that are exposed are removed by means of a wet etching method using heated phosphoric acid. By this means, as illustrated in FIG. 35 to FIG. 37, trenches 32A are formed at one end in the Y-direction of the trench 11, and trenches 32B are formed at the other end in the Y-direction of the trench 11. Four each of the trenches 32A, 32B are formed. The wet etching is performed under conditions such that the silicon nitride film is selectively removed. As a result, the protective film 25 and the insulating film 8 remain on the inner surfaces of the trenches 32A, 32B and the upper surfaces of the element isolation region 2 and the semiconductor beams 4A, 4B.

Next, an ion implantation method is used to implant arsenic via the trenches 32A, 32B into the exposed surfaces of the semiconductor beams 4, and further, the implanted arsenic is caused to diffuse by thermal diffusion in the vicinity of the boundaries between the semiconductor beams 4C and the semiconductor beams 4A, 4B. By this means, as illustrated in FIG. 37(b), the lightly doped region layers 4LA, 4LB are formed in the vicinity of the boundaries between the semiconductor beams 4C and the semiconductor beams 4A, 4B within the semiconductor beams 4. It should be noted that depictions of the lightly doped region layers 4LA, 4LB are omitted from the other drawings (for example FIG. 19 and FIG. 40 described hereinafter). This arsenic implantation is preferably performed under implantation conditions in which the implantation energy is 40 keV and the dosage is 5×10¹⁴ atoms/cm². Further, implantation is preferably performed from both sides in the Y-direction (represented by ‘+Y’ and ‘−Y’ in FIG. 37(a)) and from both sides in the X-direction (represented by ‘+X’ and ‘−X’ in FIG. 36(b)) toward the semiconductor beams 4A, 4B at a prescribed angle θ (the angle relative to the main surface of the semiconductor substrate 1). Further, it is preferable to employ heat-treatment at 1000° C. for 10 seconds as the thermal diffusion after implantation. By forming the lightly doped region layers 4LA, 4LB, the electric field at the drain end is alleviated, and the short channel effect is suppressed.

Next, a silicon dioxide film having a thickness of 100 nm is deposited over the entire surface using a CVD method, after which this is removed using a CMP method to expose the upper surface of the conductive film 12. By this means, as illustrated in FIG. 38 to FIG. 40, the interlayer insulating film 9 is formed in the interior of and above the trenches 32A, 32B, and on the upper surfaces of the element isolation region 2, the first and second substrate regions 1A, 1B and the semiconductor beams 4A, 4B. The semiconductor device 100 illustrated in FIG. 17 to FIG. 19 is completed by subsequently forming the wiring lines 13 and the like in the same way as in the first mode of embodiment.

As described hereinabove, according to this method of manufacture, the gate electrode 7 is formed using a CMP method rather than by dry etching. There is therefore no damage to the semiconductor beams 4 or the semiconductor substrate 1 resulting from dry etching of the gate electrode material.

Further, according to this method of manufacture, both end portions of the trench 11 in the Y-direction are filled using the interlayer insulating film 9 after the central portion of the trench 11 in the Y-direction has been filled using the gate electrode 7. According to such a method of manufacture, the interlayer insulating film 9 sandwiching the gate electrode 7 fulfills the role of an insulator between the gate electrode 7 and the first and second substrate regions 1A, 1B, and it is therefore possible to avoid degradation of the element characteristics resulting from positional deviation of the gate electrode 7 in the Y-direction.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention.

For example, the method of manufacture according to the second mode of embodiment may be employed not only in the manufacture of the semiconductor device 100 according to the second mode of embodiment, but also in the manufacture of the semiconductor device 100 according to the first mode of embodiment. In this case it is preferable to omit the step of forming the protective film 25 and the insulating film 26, and the step of forming the trenches 28 using the multilayer masking film 27.

Further, in the abovementioned first mode of embodiment the dopant-diffused layers 5A, 5B are not formed within the semiconductor beams 4, but in the same way as in the second mode of embodiment, the dopant-diffused layers 5A, 5B may also be provided within the semiconductor beams 4 in the first mode of embodiment.

### EXPLANATION OF THE REFERENCE NUMBERS

1 Semiconductor substrate
1A, 1B Substrate region
2 Element isolation region
4, 4A, 4B, 4C Semiconductor beam
4LA, 4LB Lightly doped region layer
5A, 5B, 5C Dopant-diffused layer
6 Gate insulating film
7 Gate electrode
8 Insulating film
9, 16 Interlayer insulating film
10, 11, 11A-11D, 28, 31, 32A, 32B Trench
12 Conductive film
13, 15A, 15B Wiring line
14A, 14B Contact plug
21, 24 Masking film
22 Photoresist
22A, 22B Open portion
23, 24 Protective film
26 Insulating film
27 Multilayer masking film
29 Recessed portion
30 Resist mask
30a Open portion
100 Semiconductor device

1. A method of manufacturing a semiconductor device, characterized in that it comprises:
a step of forming a first and a second dopant-diffused layer on the main surface of a semiconductor substrate;
a step of forming a trench on a bottom surface of which is erected at least one semiconductor beam, respectively connected at one end to the abovementioned first dopant-diffused layer and connected at the other end to the abovementioned second dopant-diffused layer;
a step of forming a gate insulating film on an inner surface of the abovementioned trench, including the side surfaces of each abovementioned at least one semiconductor beam, and on an upper surface of each abovementioned at least one semiconductor beam;
a step of depositing a gate electrode material having a film thickness that fills the abovementioned trench, after the abovementioned gate insulating film has been formed; and
a step of removing the abovementioned gate electrode material that is located outside the abovementioned trench as seen in a plan view, while leaving the abovementioned gate electrode material that is located inside the abovementioned trench as seen in a plan view.

2. The method of manufacturing a semiconductor device as claimed in claim 1, characterized in that the step of forming the abovementioned trench is carried out by etching the main surface of the abovementioned semiconductor substrate using as a mask a first masking film which covers a region corresponding to the outside of the abovementioned trench as seen in a plan view and regions overlapping each abovementioned at least one semiconductor beam, as seen in a plan view; and
the method further comprises a step of removing the abovementioned first masking film before the abovementioned gate insulating film has been formed.

3. The method of manufacturing a semiconductor device as claimed in claim 2, characterized in that the step of removing the abovementioned gate electrode material is carried out by dry etching the abovementioned gate electrode material in a state in which the abovementioned gate electrode material that is located inside the abovementioned trench as seen in a plan view is covered using a second masking film.

4. The method of manufacturing a semiconductor device as claimed in claim 1, characterized in that the step of forming the abovementioned trench is carried out by etching the main surface of the abovementioned semiconductor substrate using as a mask a first masking film which covers a region corresponding to the outside of the abovementioned trench as seen in a plan view and regions overlapping each abovementioned at least one semiconductor beam, as seen in a plan view; and
the method further comprises a step of etching the abovementioned first masking film, before the abovementioned gate insulating film has been formed, using as a mask a third masking film which covers at least a region corresponding to the outside of the abovementioned trench, as seen in a plan view, and which has an open portion exposing at least a portion of a region corresponding to the inside of the abovementioned trench as seen in a plan view.

5. The method of manufacturing a semiconductor device as claimed in claim 4, characterized in that the step of removing the abovementioned gate electrode material is carried out by performing grinding to remove at least the abovementioned gate electrode material that is located outside the abovementioned trench, as seen in a plan view.

6. The method of manufacturing a semiconductor device as claimed in claim 4, characterized in that each abovementioned at least one semiconductor beam is provided extending in a first direction; and
the abovementioned open portion exposes a central section, in the abovementioned first direction, of a region corresponding to the inside of the abovementioned trench as seen in a plan view.

7. The method of manufacturing a semiconductor device as claimed in claim 6, characterized in that it further comprises, after the step of forming the abovementioned trench and before the step of etching the abovementioned first masking film, a step of forming a fourth masking film which fills a region of the abovementioned trench that does not overlap any of the abovementioned at least one semiconductor beams as seen in a plan view; and
in the step of etching the abovementioned first masking film, the abovementioned fourth masking film is also etched, using the abovementioned third masking film as a mask.

8. The method of manufacturing a semiconductor device as claimed in claim 7, characterized in that the step of removing the abovementioned gate electrode material is carried out by performing grinding to remove the abovementioned gate electrode material that has been formed in a region in which the abovementioned first and fourth masking films overlap as seen in a plan view.

9. The method of manufacturing a semiconductor device as claimed in claim 8, characterized in that it further comprises, after the step of removing the abovementioned gate electrode material, a step of removing the abovementioned first and fourth masking films; and
a step of filling with an insulating film an empty region in the abovementioned trench generated by removing the abovementioned fourth masking film.

10. The method of manufacturing a semiconductor device as claimed in claim 1, characterized in that it further comprises a step of demarcating an active region by forming an element isolation region on the main surface of the abovementioned semiconductor substrate; and
the abovementioned trench is formed in a region overlapping respectively the abovementioned active region and the abovementioned element isolation region as seen in a plan view.

11. The method of manufacturing a semiconductor device as claimed in claim 10, characterized in that each abovementioned at least one semiconductor beam is provided extending in a first direction;
the length of the abovementioned trench in the abovementioned first direction is less than the length of the abovementioned active region in the abovementioned first direction; and
the length of the abovementioned trench in a second direction orthogonal to the abovementioned first direction is greater than the length of the abovementioned active region in the abovementioned second direction.

12. The method of manufacturing a semiconductor device as claimed in claim 11, characterized in that the abovementioned first dopant-diffused layer is formed in a first substrate region of the active region, located between one end in the abovementioned first direction of the abovementioned active region and the abovementioned trench; and
the abovementioned second dopant-diffused layer is formed in a second substrate region of the active region, located between the other end in the abovementioned first direction of the abovementioned active region and the abovementioned trench.

13. The method of manufacturing a semiconductor device as claimed in claim 12, characterized in that the abovementioned first and second dopant-diffused layers are respectively formed in such a way that they also extend out from the abovementioned first and second substrate regions into the abovementioned at least one semiconductor beam.

14. A semiconductor device characterized in that it comprises:
a first and a second dopant-diffused layer formed on the main surface of a semiconductor substrate;
a trench on a bottom surface of which is erected at least one semiconductor beam, each connected at one end to the abovementioned first dopant-diffused layer and connected at the other end to the abovementioned second dopant-diffused layer;
a gate insulating film covering an inner surface of the abovementioned trench, including the side surfaces of each abovementioned at least one semiconductor beam, and an upper surface of each abovementioned at least one semiconductor beam; and
a gate electrode covering, with the interposition of the abovementioned gate insulating film, the inner surface of the abovementioned trench, including the side surfaces of each abovementioned at least one semiconductor beam, and the upper surface of each abovementioned at least one semiconductor beam.

15. The semiconductor device as claimed in claim 14, characterized in that it further comprises an active region demarcated by means of an element isolation region formed on the main surface of the abovementioned semiconductor substrate; and
the abovementioned trench is formed in a region overlapping respectively the abovementioned active region and the abovementioned element isolation region as seen in a plan view.

16. The semiconductor device as claimed in claim 15, characterized in that each abovementioned at least one semiconductor beam is provided extending in a first direction;
the length of the abovementioned trench in the abovementioned first direction is less than the length of the abovementioned active region in the abovementioned first direction; and
the length of the abovementioned trench in a second direction orthogonal to the abovementioned first direction is greater than the length of the abovementioned active region in the abovementioned second direction.

17. The semiconductor device as claimed in claim 16, characterized in that the abovementioned first dopant-diffused layer is formed in a first substrate region of the active region, located between one end in the abovementioned first direction of the abovementioned active region and the abovementioned trench; and
the abovementioned second dopant-diffused layer is formed in a second substrate region of the active region, located between the other end in the abovementioned first direction of the abovementioned active region and the abovementioned trench.

18. The semiconductor device as claimed in claim 17, characterized in that it further comprises an insulating film formed between the abovementioned gate electrode and the abovementioned gate insulating film formed on a surface constituting the respective side surfaces of the abovementioned first and second substrate regions on the inner surface of the abovementioned trench.

19. The semiconductor device as claimed in claim 17, characterized in that the abovementioned first and second dopant-diffused layers are respectively formed in such a way that they also extend out from the abovementioned first and second substrate regions into the abovementioned at least one semiconductor beam.
